(19) United States
(12) Patent Application Publication
(10) Pub. No.: US 2011/0233512 A1
(43) Pub. Date: Sep. 29, 2011

(54) VERTICAL INTEGRATED SILICON NANOWIRE FIELD EFFECT TRANSISTORS AND METHODS OF FABRICATION

(75) Inventors: Peidong Yang, El Cerrito, CA (US); Joshua Goldberger, Chicago, IL (US); Allon Hochbaum, Berkeley, CA (US); Rong Fan, Pasadena, CA (US); Rongrui He, Albany, CA (US)

(73) Assignee: THE REGENTS OF THE UNIVERSITY OF CALIFORNIA, Oakland, CA (US)

(21) Appl. No.: 12/015,044

(22) Filed: Jan. 16, 2008

Related U.S. Application Data
(63) Continuation of application No. PCT/US2006/032153, filed on Aug. 16, 2006.
(60) Provisional application No. 60/709,044, filed on Aug. 16, 2005.

(51) Int. Cl. H01L 29/08; H01L 21/336; H01L 29/78; B82Y 99/00; B82Y 40/00

(52) U.S. Cl. 257/9; 438/268; 977/762; 257/E29.04; 257/E21.41

(57) ABSTRACT

Vertical integrated field effect transistor circuits and methods are described which are fabricated from Silicon, Germanium, or a combination Silicon and Germanium based on nanowires grown in place on the substrate. By way of example, vertical integrated transistors are formed from one or more nanowires which have been insulated, had a gate deposited thereon, and to which a drain is coupled to the exposed tips of one or more of the nanowires. The nanowires are preferably grown over a surface or according to a desired pattern in response to dispersing metal nanoclusters over the desired portions of the substrate. In one preferred implementation, SiCl₄ is utilized as a gas phase precursor during the nanowire growth process. In place nanowire growth is also taught in conjunction with structures, such as trenches, while bridging forms of nanowires are also described.

### CROSS-REFERENCE TO RELATED APPLICATIONS

This application claims priority from, and is a 35 U.S.C. §111(a) continuation of, co-pending PCT international application serial number PCT/US2006/032153, filed on Aug. 16, 2006, incorporated herein by reference in its entirety, which claims priority from U.S. provisional application Ser. No. 60/709,044 filed on Aug. 16, 2005, incorporated herein by reference in its entirety.

This application is related to PCT International Publication No. WO 2007/022359 A2, published on 22 Feb. 2007, incorporated herein by reference in its entirety.

### STATEMENT REGARDING FEDERALLY SPONSORED RESEARCH OR DEVELOPMENT

This invention was made with Government support under Grant No. DE-FG02-02ER46021, awarded by the Department of Energy. The Government has certain rights in this invention.

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

A portion of the material in this patent document is also subject to protection under the maskwork registration laws of the United States and of other countries. The owner of the maskwork rights has no objection to the facsimile reproduction by anyone of the patent document or the patent disclosure, as it appears in the United States Patent and Trademark Office publicly available file or records, but otherwise reserves all maskwork rights whatsoever. The maskwork owner does not hereby waive any of its rights to have this patent document maintained in secrecy, including without limitation its rights pursuant to 37 C.F.R. §1.14.

### BACKGROUND OF THE INVENTION

1. Field of the Invention

This invention pertains generally to nanowire fabrication, and more particularly to vertical integrated transistors fabricated from nanowires.

2. Description of Related Art

As semiconductor devices are scaled into the sub 50 nm regime, short-channel effects and poor sub-threshold characteristics begin to be problematic for traditional planar transistors. Novel device geometries with enhanced performance, defined by functional density, energy efficiency, scalability, and compatibility with CMOS, are required in order to push toward ever higher packing densities in devices and circuits, such as memories and logic chips, to provide ever increasing energy efficiency.

Silicon nanowires have received considerable attention as transistor components because they represent a facile route towards sub-100 nm single-crystalline Si features with minimal surface roughness. Typically, silicon nanowire transistors have a horizontal planar layout with either a top or back gate geometry. However, the difficulty in reliably assembling ultra-high density planar nanowire circuits, combined with the performance limitations of the horizontal device geometry may ultimately hinder nanowire-based electronics from realizing their full potential.

Therefore, a need exists for transistor geometries and fabrication methods which are amenable to high density fabrication, the nanowire transistors and fabrication methods according to the present invention fulfill that need as well as others and overcome shortcomings with traditional nanowire fabrication.

### BRIEF SUMMARY OF THE INVENTION

The present invention comprises a vertical integrated nanowire field effect transistor (VINFET) and a method of fabricating the VINFET about a vertical nanowire. Methods are described for growing nanowires from a substrate. In one embodiment of the invention, a field effect transistor is fabricated from a vertical nanowire extending from a substrate base. The transistor comprises the nanowire coupled to the source, surrounded by a gate dielectric about which a metal gate is formed. A drain is coupled to the exposed tip of the nanowire and insulated from the conductive gate. The transistor can be fabricated with a single nanowire or any desired number of nanowires coupled between the source and a given drain region or pad.

By way of example and not limitation, in one embodiment the vertical integrated nanowire field effect transistor (VINFETs) is fabricated in place according to the following general processing procedure. First, Si nanowires are grown vertically from a Si (111) substrate. After nanowire growth, the nanoparticle catalysts are etched away and cleaned. The substrates are then oxidized to achieve the desired gate SiO₂ dielectric thickness. Cr gate metal is deposited, such as by sputtering, to achieve a conformal coating. Alternatively, LPCVD techniques can be used to deposit the desired gate materials (i.e., poly-Si, metal silicides) for threshold voltage tuning. A dielectric is then deposited for formed, for example forming a conformal low pressure chemical vapor deposition (LPCVD) SiO₂ dielectric deposited onto the substrate and nanowire. A gate pattern is then defined, such as by using standard photolithographic techniques. After developing the photoresist gate pattern, etch windows are created by plasma etching the exposed SiO₂ areas. The undesired Cr is then removed.

At this point the tips of the nanowires are still coated with the Cr gate metal. This material is then removed so as to prevent electrical shorting between the drain and gate electrodes. A combination of chemomechanical polishing and SiO₂ plasma etching techniques is suitable to expose the nanowire tips. The Cr surrounding the tips of the nanowires is then removed. A second coating of LPCVD SiO₂ is deposited onto the substrates to electrically isolate the gate and drain materials. Square drain pads are then photolithographically defined. The nanowire tips are subsequently exposed via SiO₂ plasma etching. SiO₂ is removed from the top of the nanowires in order to increase the contact surface area. Ni (50 nm)/Pt (30 nm) contacts are sputtered onto the drain regions, and NiSi contacts are formed after a rapid thermal annealing treatment. Before the final source contact is made, photoresist is spun onto the top device side of the substrate to protect the nanowire circuitry. Al contacts are thermally evaporated onto the backside of the substrates, after oxide removal. The device is subsequently annealed to achieve lower contact resistance.

In another embodiment, vertical integrated nanowire field effect transistors (VINFETs) are fabricated according to the following processing procedure. First, Si nanowires are grown vertically from a Si (111) substrate. After nanowire growth, the nanoparticle catalysts are etched away, for example by using aqua regia, followed by a standard water and isopropanol rinse, 7 min 300 W O₂ plasma clean. The substrates are then oxidized, for instance at 850° C. for 4-8 hours to achieve the desired gate SiO₂ dielectric thickness. Cr gate metal is preferably sputtered on to achieve a conformal coating, for example of 50-100 nm in this implementation. Alternatively, LPCVD techniques can be used to deposit the desired gate materials (i.e., poly-Si, metal silicides) for the desired threshold voltage tuning. From approximately 750-4000 nm of conformal low pressure chemical vapor deposition (LPCVD) SiO2 dielectric is then deposited onto the substrates. A gate pattern is then defined for example via standard photolithographic techniques. After developing the photoresist gate pattern, etch windows are created such as by performing plasma etching of the exposed SiO₂ areas using a LAM Research Corporation AutoEtch Plasma Etch System. The undesired Cr is removed, for example using Cr-7 Photomask etchant from Cyantek.

At this point the tips of the nanowires are still coated with the Cr gate metal. This material is then removed so as to prevent electrical shorting between the drain and gate electrodes. A combination of chemomechanical polishing and SiO₂ plasma etching techniques is suited for exposing the nanowire tips. The Cr surrounding the tips of the nanowires is then removed using Cr-7 etchant. A second dielectric coating is then formed, such as in the range of approximately 300-750 nm coating of LPCVD SiO₂ deposited onto the substrates to electrically isolate the gate and drain materials. Approximately 70 μm×70 μm square drain pads are preferably photolithographically defined. The nanowire tips are subsequently exposed, such as via SiO₂ plasma etching. SiO₂ is removed from the top 50 nm of the nanowires in order to increase the contact surface area. Contacts are then formed, by way of example as Ni (50 nm)/Pt (30 nm) contacts sputtered onto the drain regions, and NiSi contacts formed after a two minute rapid thermal annealing treatment at 400° C. Before the final source contact is made, photoresist is applied, such as being spun onto the top device side of the substrate to protect the nanowire circuitry. Al contacts are thermally evaporated onto the backside of the substrates, after oxide removal via SiO₂ plasma etching and 10:1 buffered HF. The device is subsequently annealed at 300° C., to achieve lower contact resistance.

Patterned nanowire growth is described on structures, such as within channels, and channel sidewalls. In addition, bridging nanowires are described for being grown between structures. These various grown nanowires can be utilized for fabricating active or passive circuits, electromechanical devices and mechanical devices.

The invention is amenable to being embodied in a number of ways, including but not limited to the following descriptions.

One implementation according to the inventive teachings is a field effect transistor, comprising: (a) a nanowire extending from a substrate base, (i.e., in a substantially vertical direction from a horizontal substrate) and preferably grown therefrom; (b) a dielectric material surrounding at least a portion of the nanowire (e.g., vertical portion and/or circumferential portion but more preferably fully circumferentially surrounding the vertical nanowire along a portion of its length); (c) a gate material (i.e., Cr) surrounding at least a portion of the dielectric material; wherein the nanowire has an exposed tip, which is not covered with the dielectric material or the gate material; and (d) a drain material coupled to the exposed tip of the nanowire. The vertical integrated nanowire field effect transistor (VINFET) described can be configured for operation within any device, circuit or system.

Each vertical transistor can be formed from a single nanowire, or from a plurality of vertical nanowires, which extend from the substrate base and are coupled to the drain material of a single drain contact pad. The nanowire, or nanowires, for each vertical integrated transistor are grown from the substrate base. The growth orientation of the nanowires is preferably controlled by utilizing epitaxial crystal growth techniques. Implementations are described in which nanowires are grown according to a vapor-liquid-solid (VLS) process, or a vapor-liquid-solid epitaxy (VLSE) process. Growth proceeds utilizing SiCl4 as a gas phase precursor, without the need of separately incorporating HCl gas, during growing of the nanowire.

The nanowires are preferably grown from Si or Ge with any desired type and level of dopants. It should be appreciated that the material or dopant properties may be varied during nanowire growth to form a longitudinally patterned nanowire (i.e., modulating dopant type, level, or even material, such as between Ge and Si). Nanowire diameter is preferably controlled in response to the diameter of the alloy droplet utilized to catalyze nanowire growth from the substrate. A plurality of alloy droplets are contained within a colloidal metal (i.e., gold (Au)) which is dispersed on the surface of the substrate prior to growth of a plurality of nanowires. Nanowires grow on the substrate at sites of alloy droplets as these become overly saturated with the desired growth species. The alloy droplets are distributed across at least a portion of the substrate surface as monodispersed metal nanoclusters.

The substrate can be patterned with metal nanoclusters so that nanowires are grown only in selected areas. Patterning can be performed utilizing any desired method, for example via micro-contact printing.

An implementation can be described as a method of fabricating a vertical integrated nanowire field effect transistor, comprising: (a) growing a nanowire vertically in-place on a substrate (i.e., Si (111)); (b) etching away nanoparticle catalysts; (c) forming a desired gate dielectric thickness (i.e., oxidation to form SiO₂ layer); (d) depositing a gate metal (i.e., Cr) on the nanowire to achieve a conformal coating; (e) depositing a dielectric onto the substrate; (f) etching undesired gate metal wherein the nanowire has an uncoated tip; (g) depositing a dielectric onto the substrate to electrically isolate the gate and drain materials; and (h) forming a drain pad in contact with the exposed tip of said nanowire. It is also preferred that the device be annealed to lower contact resistance.

The nanowire growth phase preferably comprises: (1) dispersing metal nanoclusters of a desired diameter over one or more portions of the substrate, or within a pattern; and (2) epitaxially growing the nanowires to a desired length utilizing SiCl4 as a gas phase precursor.

Embodiments of the present invention can provide a number of beneficial aspects which can be implemented either separately or in any desired combination without departing from the present teachings.

An aspect of the invention comprises a vertical integrated nanowire field effect transistor.

Another aspect of the invention comprises devices, circuits and systems fabricated using vertical integrated nanowire field effect transistors.

Another aspect of the invention is the fabrication of vertical integrated nanowire transistors having consistent gate diameters.

Another aspect of the invention comprises growing nanowires in place from a substrate.

Another aspect of the invention comprises utilizing single nanowires, or more preferably any desired plurality of nanowires, to form channels within a single device.

Another aspect of the invention comprises controlling the diameter of nanowire growth in response to the diameter of the metal nanoclusters as seeds.

Another aspect of the invention comprises controlling the length of the nanowire in response to growth time.

Another aspect of the invention comprises controlling distribution of metal nanoclusters by dispersing the nanoclusters such as within a colloidal metal.

Another aspect of the invention comprises growing nanowires within a trench or other structure, while retaining desired growth direction.

Another aspect of the invention comprises growing nanowire bridges between structures on a substrate.

Still another aspect of the invention is the direct integration of nanowire growth into the fabrication process, such as of vertical integrated nanowire transistors.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a schematic depicting conventional vapor-liquid-solid nanowire growth mechanisms with distributed metal catalysts, alloying, nucleation, and axial nanowire growth.

FIG. 2A-2F are TEM images recorded during the nanowire growth process, showing Au nanoclusters in solid state at 500 C in FIG. 2A; alloying initiated at 800 C in FIG. 2B; liquid Au/Ge alloy in FIG. 2C; nucleation of a Ge nanocrystal on the alloy surface in FIG. 2D; Ge nanocrystal elongation in response to further Ge condensation in FIG. 2E; and formation of a wire in FIG. 2F.

FIG. 3A-3B are TEM images of a vertical silicon (Si) nanowire array grown on a (111) crystal-oriented Si wafer, with monodispersed diameter, according to an aspect of the present invention.

FIG. 4 is a STEM image of two Si/Ge superlattice nanowires in the bright-field mode as grown according to an aspect of the present invention.

FIG. 5A-5F are schematics of vertical silicon nanowires surrounding gate transistors within different possible array and stack structures, according to an aspect of the present invention.

FIG. 6 is a schematic of a silicon nanowire vertical integrated field effect transistor, according to an aspect of the present invention.

FIG. 7A-7C are schematics of a VINFET device fabrication process, according to an aspect of the present invention.

FIG. 8A is a scanning electron microscopy image of a VINFET device before drain contact, according to an aspect of the present invention.

FIG. 8B is a graph of ambipolar behavior of the VINFET of FIG. 8A.

FIG. 9A-9B are images of Si Nanowires, grown according to an aspect of the present invention, showing a cross-sectional SEM image of vertically grown Si nanowires off of a Si (111) substrate in FIG. 9A; and TEM image of Si nanowire surrounded in a conformal SiO2 coating in FIG. 9B.

FIG. 10A is a schematic of VINFET device fabrication from vertical silicon nanowires, according to an aspect of the present invention.

FIG. 10B-10D are images of VINFET fabrication as in FIG. 10A, showing top-view SEM images of a completed VINFET device in FIG. 10B; mid-section in FIG. 10C; cross-sectional image of a VINFET device in FIG. 10D.

FIG. 11A-11D are graphs of VINFET device characteristics for devices fabricated according to the present invention.

FIG. 12A is a schematic of a VINFET inverter circuit.

FIG. 12B is a graph of VINFET characteristics for a device fabricated according to an aspect of the present invention, having multiple nanowires connected in parallel, which is shown to exhibit a substantial gain.

FIG. 13A-13C are schematics of Si VINFET fabrication, according to an aspect of the present invention, showing Si nanowires grown in FIG. 13A, thermal oxidation to form gate oxide dielectric in FIG. 13B, and forming a Cr gate in FIG. 13C.

FIG. 14A-14C are schematics of Si VINFET fabrication, according to an aspect of the present invention, showing LPCVD oxide deposition in FIG. 14A; exposing nanowire tips in FIG. 14B; and etching back Cr gate material using Cr photomask etchant in FIG. 14C.

FIG. 14D-14F are images of the Si VINFET device in response to steps shown respectively in FIG. 14A-14C.

FIG. 15A-15C are schematics of Si VINFET fabrication, according to an embodiment of the present invention, showing another layer of dielectric formed onto the nanowire in FIG. 15A; exposing nanowire tips in FIG. 15B; and forming drain electrode in FIG. 15C.

FIGS. 16 A-16F are images and associated size distributions for nanowire samples fabricated according to an aspect of the present invention.

FIG. 17A is a graph of SiNW growth density in relation to the relative concentration of the colloidal metal seeding solution, according to an aspect of the present invention.

FIG. 17B-17C are images of typical nanowire growth at: 4/5 in FIG. 17B and 2/5 dilution in FIG. 17C.

FIG. 18A is a schematic of PDMS patterning of Au colloids, according to an aspect of the present invention.

FIG. 18B-18C are SEM images of PDMS patterned SiNW growth in a side view as per FIG. 18B, and in a plan-view of the same in FIG. 18C.

FIG. 19A-19C are images of Si nanowires grown directly in a micro-fabricated trench-channel, according to an embodiment of the present invention.

FIG. 20A is a schematic of Si nanowire bridge growth steps in micro-fabricated trenches, according to an aspect of the present invention.

FIG. 20B-20C are images of parallel trenches formed on a SOI wafer in FIG. 20B; and of nanowire bridges grown in trenches in FIG. 20C.

FIG. 21A-21C are SEM images of epitaxial alignment and interface cleanliness for Si nanowire growth in trenches, according to an aspect of the present invention, showing <111> crystallographic alignment in FIG. 21A, and magnifications in FIGS. 21B and 21C.

FIG. 21D is a graph of X-ray photoelectron spectra of Si 2p region of FIG. 21A.

FIG. 22A-22D are images of connections established between Si nanowires and trench sidewalls, according to an aspect of the present invention.

FIG. 23A-23C are images of Si nanowire bridging according to an aspect of the present invention, showing control of length in FIG. 23A, diameter in FIG. 23B; and density of bridging Si nanowires in FIG. 23C.

FIG. 24A is an SEM image of a nanowire-in-trench structure according to an embodiment of the present invention.

FIG. 24B is a graph of electrical measurements of the nanowire-in-trench structure of FIG. 24A illustrating current-voltage curves.

### DETAILED DESCRIPTION OF THE INVENTION

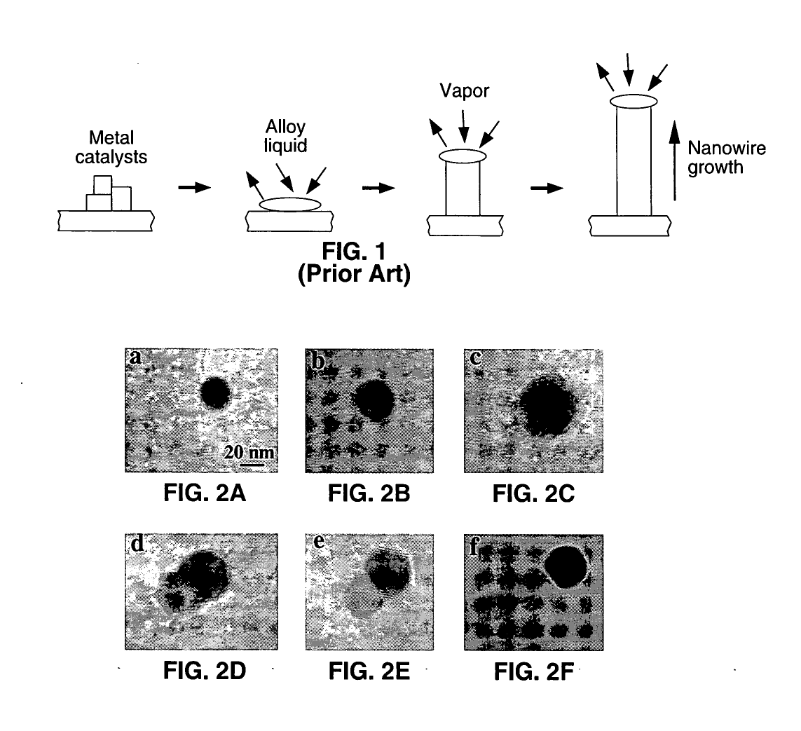

Referring more specifically to the drawings, for illustrative purposes the present invention is embodied in the apparatus and methods generally shown in FIG. 1 through FIG. 24B. It will be appreciated that the apparatus may vary as to configuration and as to details of the parts, and that the method may vary as to the specific steps and sequence, without departing from the basic concepts as disclosed herein.

1. Silicon Nanowire Vertical integrated Surrounding-Gate FET.

As semiconductor devices are scaled into the sub 50 nm regime, short-channel effects and poor sub-threshold characteristics begin to be problematic for traditional planar transistors. Novel vertical integrated surrounding gate field-effect transistor (FET) device geometries are described which provide enhanced performance, as defined by improvements in functional density, energy efficiency, scalability, and compatibility with CMOS, are required in order to push toward ever higher packing densities with ever increasing energy efficiency, such as within memory and logic chips and circuits.

By way of example, a number of objectives are outlined below for this portion of the invention. (a) Creating a process of vertical integrated silicon nanowire array growth that provides tight control over size (such as <20 nm), uniformity (such as ±10%), position (such as is amenable to addressability), density (such as on the order of 106-10¹² cm⁻²; scalability), and precise doping. (b) Demonstrate the first silicon nanowire vertical integrated surrounding gate transistor (Si-NW-SGT). (c) Propose the integration of Si nanowire vertical integrated surrounding gate transistors into arrays and stacks for memory and logic technologies.

In the process of transistor scaling, the introduction of several important device concepts in the past decade has been witnessed, such as: double-gate, tri-gate MOSFET, FinFET and surrounding gate MOSFET. In particular, the surrounding gate devices have the benefits of both reducing the channel effects and improving the sub-threshold characteristics, as well as providing significantly higher packing densities. The conceptual demonstration of these proposed device geometries has all been performed via the traditional top-down micro-fabrication processes (i.e., etching vertical structures into a substrate). In contrast, the current proposal relies on a bottom-up process (i.e., growing vertical structures from a substrate) to produce the precisely defined “channel” (epitaxial silicon nanowire vertical array) of the proposed surrounding gate transistors. The proposed vertical geometry also readily differentiates from the previous work on nanowire transistors, all of which adopt a lateral device geometry.

It should be appreciated that “vertical” is described herein in relation with a horizontal substrate, however, the nanowire transistors can be fabricated in a desired orientation (e.g., orthogonal, or along any given crystal orientation) which extends from a substrate surface.

Fabrication Approach.

Nanoscale one-dimensional materials have stimulated great interest due to their importance in basic scientific research and potential technology applications. Many unique and fascinating properties have been proposed and demonstrated for this class of materials, such as superior mechanical toughness, higher luminescence efficiency, and enhancement of thermoelectric figure of merit. Semiconductor nanowires are being considered as critical building blocks to assemble new generations of nanoscale electronic circuits and photonics.

Vapor-Liquid-Solid Epitaxial Growth of Nanowire Arrays

One accepted mechanism of nanowire growth through a gas-phase reaction is the vapor-liquid-solid (VLS) process proposed by Wagner in 1960s during his studies of large single-crystalline whisker growth. According to this mechanism, the anisotropic crystal growth is promoted by the presence of a liquid alloy/solid interface.

FIG. 1 illustrates the process of Si nanowire growth by using Au clusters as the solvent at high temperature including seeding with a metal catalyst, followed by the three stages of alloying, nucleation and axial growth. Based on a Si—Au binary phase diagram, Si (from the decomposition of SiH₄, for example) and Au will form a liquid alloy when the temperature is higher than the eutectic point (363 C). The liquid surface has a large accommodation coefficient and is therefore a preferred deposition site for incoming Si vapor. After the liquid alloy becomes supersaturated with Si, Si nanowire growth occurs by precipitation at the solid-liquid interface.

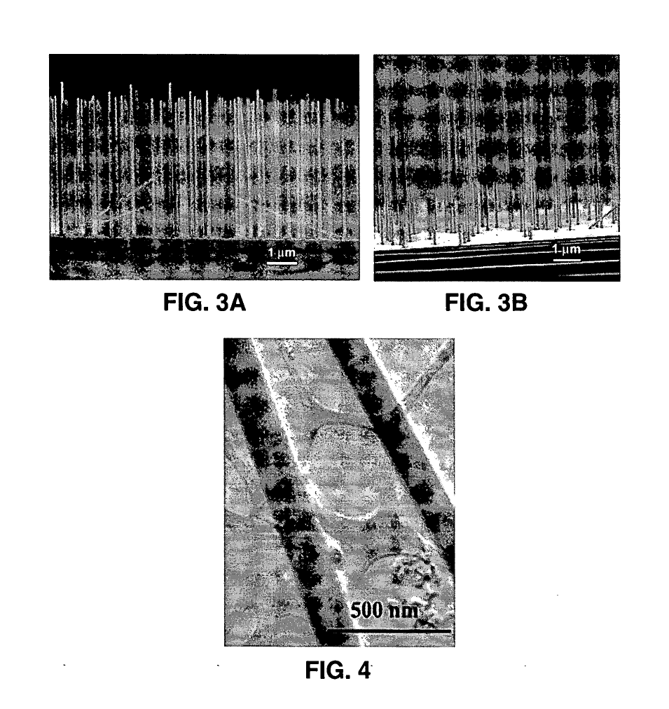

FIG. 2A-2F are example images taken in this lab which provide real-time observation of Ge nanowire growth conducted in a high-temperature in-situ transmission electron microscope (TEM). FIG. 2A shows Au nanoclusters in solid state at 500 C. FIG. 2B illustrates initiating of alloying at 800 C. FIG. 2C depicts liquid Au/Ge alloy, with nucleation of a Ge nanocrystal on the alloy surface shown in FIG. 2D. FIG. 2E shows Ge nanocrystal elongation in response to further Ge condensation with nanowire formation in FIG. 2F.

The results clearly show three growth stages: formation of Au—Ge alloy (FIG. 2B, 2C), nucleation of Ge nanocrystal (FIG. 2D) and elongation of Ge nanowire (FIG. 2E, 2F). These tests unambiguously demonstrate the validity of the VLS mechanism for nanowire growth. The establishment of a VLS mechanism at the nanometer scale is very important for the rational control of inorganic nanowires, since it provides the necessary underpinning for the prediction of metal solvents and optimized preparation conditions.

Based on our mechanism of nanowire growth we will demonstrate that one can achieve controlled growth of nanowires at different levels. The diameter of nanowire is determined by the size of the alloy droplet, which is in turn determined by the original cluster size. By using monodispersed metal nanoclusters, nanowires with a narrow diameter distribution can be synthesized. In addition, controlling the growth orientation is important for many of the proposed applications of nanowires, particularly for the vertical integrated transistor application taught herein. By applying the conventional epitaxial crystal growth technique into this VLS process, it is possible to achieve precise orientation control during the nanowire growth. The vapor-liquid-solid epitaxy (VLSE) technique is particularly powerful in controlled synthesis of nanowire arrays.

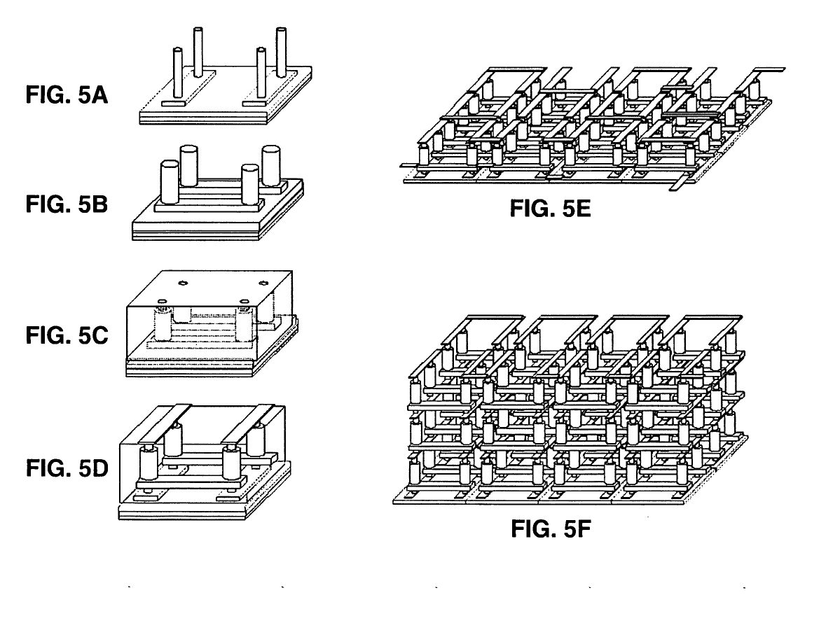

FIG. 3A-3B are images depicting the formation of a highly uniform nanowire array. By way of example, Si is used with a (111) Si wafer as a substrate, upon which Si nanowires are grown epitaxially and vertically. The nanowires are highly uniform (in this case 60±5 nm in diameter). The length of the nanowires can be readily tuned from 1 μm to 10 μm by adjusting the growth time.

This VLSE method is described herein for growing silicon nanowire arrays with tight control over size (i.e., diameter<20 nm) and uniformity (i.e., <±10%). To demonstrate the scalability of this method the nanowire density will be controlled in the range of 10⁶-10¹² cm⁻² by adjusting the initial nanocluster density on the substrates. In addition, in order to be able to address individual vertical integrated transistors, we propose to pattern the nanoclusters on the substrate to produce an ordered nanowire array, hence producing an addressable ultra-high density vertical integrated transistor array.

For the vertical integrated transistor to be functional, the precise doping within the nanowire represents a critical issue. Within the framework of VLS growth, suitable chemical vapor deposition conditions need to be mapped out so that possible surface diffusion of the dopants can be avoided. Beyond chemical doping, the VLS mechanism also allows the direct growth of longitudinal heterostructured nanowires, which should open up further technological opportunities.

Researchers in this lab recently demonstrated the use of a hybrid pulsed laser ablation/chemical vapor deposition process for generating semiconductor nanowires with periodic longitudinal heterostructures. In this process, Si and Ge vapor sources were independently controlled and alternately delivered into the VLS nanowire growth system. As a result, single crystalline nanowires containing the Si/SiGe superlattice structure were obtained.

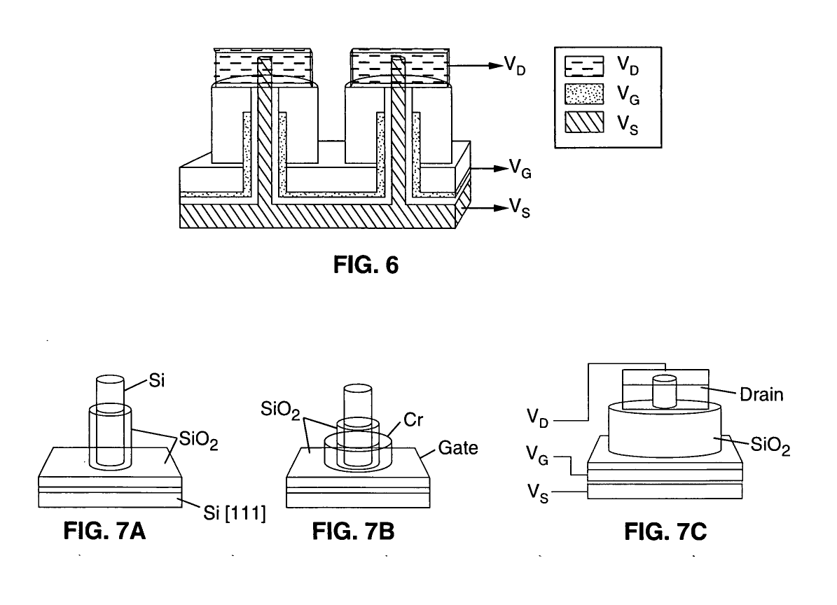

FIG. 4 depicts a scanning transmission electron microscopy (STEM) image of two such nanowires in the bright-field mode. Dark stripes appear periodically along the longitudinal axis of each wire, reflecting the alternating domains of Si and SiGe alloy. Since the supply of vapor sources can be readily programmed, the VLS process with modulated sources is useful for preparing a variety of heterostructures on individual nanowires in a “custom-designed” fashion. It will also enable the creation of various functional devices (e.g., p-n junctions, coupled quantum dot structures, and heterostructured unipolar and bipolar transistors) on individual nanowires. These heterostructured nanowires can be further used as important building blocks to construct nanoscale electronic circuits and light emitting devices.

Silicon Nano Wire Vertical Integrated Surrounding-Gate FET

Vertical silicon nanowire (and superlattice nanowire) arrays, when fabricated with tight control over size (<20 nm), uniformity (±10%), and precise doping, provide an excellent material platform for the fabrication of the vertical integrated surrounding gate transistors.

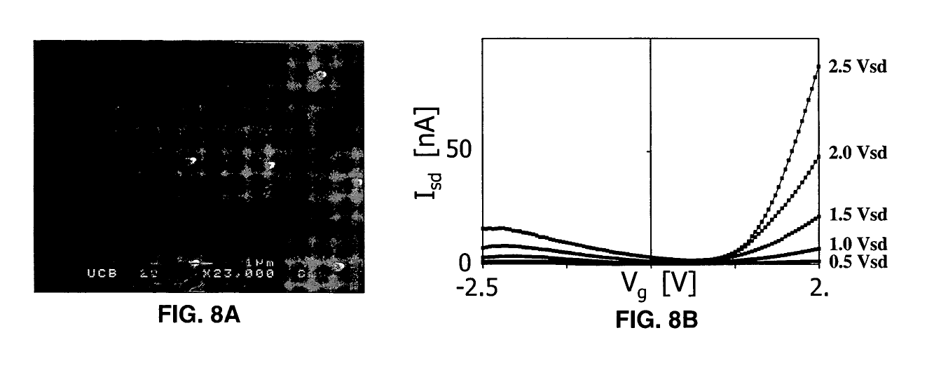

FIG. 5A-5F illustrate silicon nanowire vertical integrated surrounding gate transistors in a variety of possible arrays and stacks. Illustrated in FIG. 5A through 5D, one can see how a circuit cell, or small structure, can be formed with integral vertical transistors coupled between conductive paths on different layers of the circuit. In addition, it should be appreciated that nanowires can be grown from any level of the circuit followed by the fabrication of VINFET transistors on those grown nanowires, wherein three-dimensional structures, such as shown in FIG. 5F, can be built up from multiple single layer two-dimensional structures as shown in FIG. 5E. It will be appreciated that dielectric structure fills may be present from which each succeeding layer may be built, however, these are not shown in the associated circuit structures for the sake of clarity. The vertical scalability of the process is readily seen from these diagrams additional details for which follow.

To demonstrate the device concept, we start with the fabrication of a single nanowire vertical integrated surrounding gate transistor. The substrate is patterned, such as with a low density of metal nanoclusters (10⁻⁶ cm⁻²) which will be used to grow isolated nanowires. This is followed by forming a gate dielectric, for example by the use of controlled thermal oxidation of the silicon nanowires to create a dielectric oxide of suitable thickness.

Alternatively, high-k dielectrics (such as HfO₂) can also be conformally coated on the nanowire surface, such as via atomic layer deposition. The degenerated substrate will be used as the source electrode contact. The gate electrode is then be deposited to surround the dielectric material (or at least a substantial portion thereof) which overlays the nanowire. The gating step is preferably followed with multiple steps of polishing, etching and final deposition of a drain metal electrode, for example as seen in FIG. 5A.

The present technique has been independently corroborated. A group at NASA demonstrated a vertical nanowire transistor based on the VLSE technique using isolated ZnO nanowires as based on a prior patent application of this lab. Their successful demonstration of the ZnO nanowire vertical transistor indicated that the proposed transistor may be feasible. The much more technological relevant silicon nanowire vertical integrated transistor demonstrated herein further required (1) developing a process for growing vertical silicon nanowires (which was demonstrated here); (2) developing different processes for making a silicon VINFET, and (3) controlling array distribution, density and nanowire size, such as with different diameters (60 nm, 40 nm, 20 nm and sub 10 nm).

Following the demonstration of fabricating a single silicon nanowire vertical integrated transistor, we synthesized high density, ordered, silicon nanowire arrays in order to create high density, addressable silicon nanowire vertical integrated transistor arrays and stacks (FIG. 5B-F).

### 2. Silicon Nanowire Vertical Integrated Surrounding-Gate FET.

Semiconductor nanowires are being considered as critical building blocks to assemble new generations of nanoscale electronic circuits and photonics.

Vapor-Liquid-Solid Epitaxial Growth of Nanowire Arrays

Based on our mechanisms and study of nanowire growth, we have found it possible to achieve controlled growth of nanowires at different levels. The diameter of nanowires can be controlled in response to the size of the alloy droplet, which is in turn determined by the original cluster size. By using monodispersed metal nanoclusters, nanowires with a narrow diameter distribution can be synthesized. In addition, controlling the growth orientation is important in a number of proposed applications for nanowires, particularly for the vertical integrated transistor application put forth herein. By applying the conventional epitaxial crystal growth technique into this VLS process, it is possible to achieve precise orientation control during nanowire growth. This technique, vapor-liquid-solid epitaxy (VLSE), is particularly well-suited in the controlled synthesis of nanowire arrays.

An example of growing Si nanowires was shown in a preceding section relating to FIG. 3A-3B. Using Si as an example, if a (111) Si wafer is used as a substrate, Si nanowires will grow epitaxially and vertically on the substrate and form a nanowire array as shown. The nanowires grown according to this method are highly uniform (60±5 nm in diameter). The length of the nanowires can be readily tuned from 1 μm to 10 μm by adjusting growth time. Aspects of the present invention utilize this VLSE technique to grow silicon nanowire arrays with tight control over size (diameter<20 nm) and uniformity (<±10%). To demonstrate the scalability of the proposed concept, nanowire density is also controlled in the range of from approximately 10⁶-10¹² cm⁻² by adjusting the initial nanocluster density on substrates. In addition, to address individual vertical integrated transistors, patterning of the nanoclusters is demonstrated on substrates to produce ordered nanowire arrays, with the object of creating addressable ultra-high density vertical integrated transistor arrays.

For the vertical integrated transistor to be functional, the precise doping within the nanowire is a critical issue. Within the framework of VLS growth, suitable chemical vapor deposition conditions need to be mapped out to avoid surface diffusion of the dopants. Beyond chemical doping, the VLS mechanism also allows the direct growth of longitudinal heterostructured nanowires, which should open up further technological opportunities.

As mentioned above, researchers in this lab recently demonstrated the use of a hybrid pulsed laser ablation/chemical vapor deposition process for generating semiconductor nanowires with periodic longitudinal heterostructures. Since the supply of vapor sources can be readily programmed, the VLS process with modulated sources is useful for preparing a variety of heterostructures on individual nanowires in a “custom-designed” fashion. It will also enable the creation of various functional devices (e.g., p-n junctions, coupled quantum dot structures, and heterostructured unipolar and bipolar transistors) on individual nanowires. These heterostructured nanowires can be further used as important building blocks to construct nanoscale electronic circuits and light emitting devices.

Silicon Nanowire Vertical Integrated Surrounding-Gate FETs.

Vertical silicon nanowire (and superlattice nanowire) arrays, with tight control over size (<20 nm), uniformity (±10%), and precise doping, provide an excellent material platform for the fabrication of vertical integrated surrounding gate transistors.

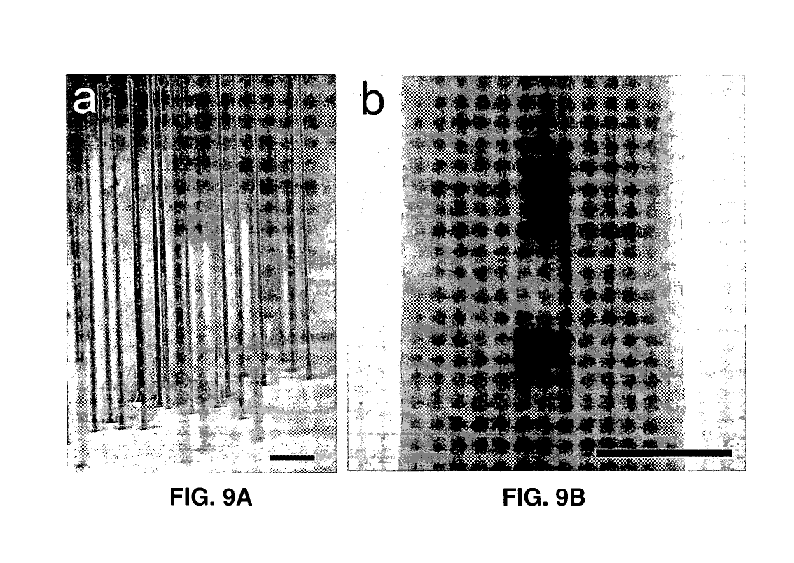

FIG. 6 illustrates an embodiment of a silicon nanowire vertical integrated field effect transistor having a gate that surrounds a nanowire grown from the substrate, and that is thus disposed between a source and drain.

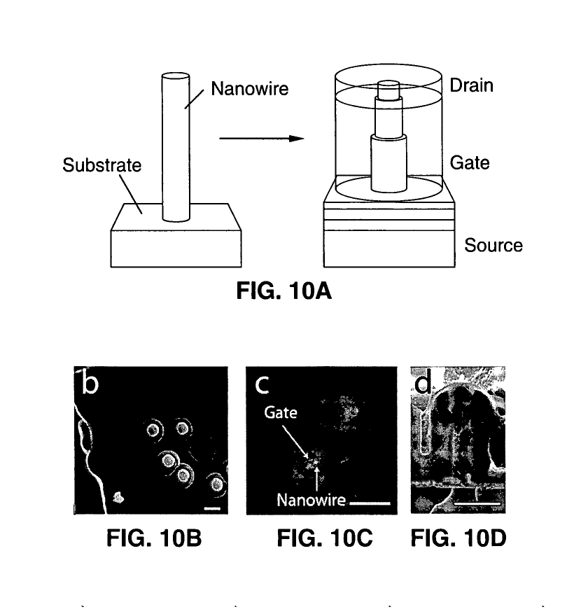

FIG. 7A-7C illustrate steps in the fabrication of an array of nanowire vertical integrated surrounding gate transistors (VINFET) as depicted in cross-section in FIG. 6. A substrate is patterned with a low density of metal nanoclusters (i.e., 10⁻⁶ cm⁻²) for growing isolated nanowires. This is followed by controlled thermal oxidation of the silicon nanowires to create the dielectric oxide (i.e., SiO₂) of suitable thickness. Alternatively, high-k dielectrics (such as HfO₂) can also be conformally coated on the nanowire surface via atomic layer deposition. The degenerated substrate is used in this implementation as the source electrode contact, resulting in the structure shown in FIG. 7A.

The gate electrode in this case is deposited surrounding the dielectrics, as shown in FIG. 7B. Finally multiple steps of polishing, etching and final deposition of a drain metal electrode are carried out resulting in the VINFET device of FIG. 7C.

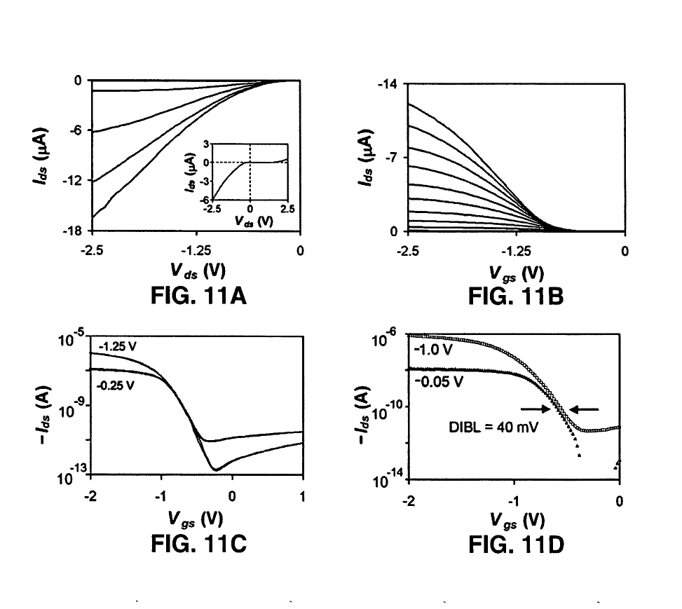

FIG. 8A and FIG. 8B depicts an SEM image of a VINFET device with a graph of its ambipolar behavior. In FIG. 8A the VINFET is shown after forming the gate electrode contact, but before the final step of drain electrode contact. With regard to the image, it should be noted that each individual bright spot in the cylindrical feature represents an individual vertical silicon nanowire channel. For the intrinsic nanowires prepared in this lab using SiCl₄ as sources, we found that they exhibit ambipolar behavior as can be seen from FIG. 8B. The observation of this ambipolar behavior is possibly a result of right carrier concentration within these intrinsic silicon nanowires although systematic studies should be carried forward to explore various doping conditions and optimization of VFET device performance including carrier mobility, and sub-threshold characteristics.

3. Vertical integrated Silicon Nanowire Field Effect Transistors.

Pushing the transistor geometry into the third dimension beneficially results in creating ultra-high transistor densities without the need for multi-step post-growth nanowire alignment processes. In addition, a vertical nanowire geometry promises enhanced transistor performance due to a surround-gate design. Herein the integration of vertically grown Si nanowire arrays into vertical integrated field effect transistors with a surround-gate architecture is demonstrated. These vertical integrated nanowire field-effect-transistors (VINFETs) exhibit excellent electronic properties comparable to traditional metal-oxide silicon field effect transistors (MOSFETs), suggesting that further optimization of this device structure may make them competitive with high-performance double-gate Fin field-effect transistors (FINFET) for future nanoelectronic devices. A VINFET based inverter demonstrates the feasibility of these devices for future logic and memory applications.

Moore's Law emphasizes the pace at which transistor sizes are reduced in order to increase the speed and density of transistors on an integrated circuit. However, conventional planar MOSFETs run into various performance limitations as gate-lengths are reduced below 50 nm. This is due to the inability of the gate electrode to effectively control source-drain current (a problem known as the short channel effect (SCE)), as well as the difficulty in proportionally scaling down gate oxide thickness and threshold voltage. These shortcomings result in significantly increased power consumption per transistor.

In order to further miniaturize the transistor while maintaining control over power consumption, alternative transistor geometries must be considered. Two such approaches are found in the use of silicon nanowire based devices and horizontal double-gate transistors. One example of horizontal double-gate transistors is known as a FINFET, whose structure is based on horizontal silicon fins sandwiched between two gate electrodes. Both of these approaches have exhibited large device mobilities and significantly reduced SCEs on the sub-100 nm scale. The FINFET has clearly demonstrated that the electrostatic efficiency of the gate electrode geometry is essential in reducing power consumption and overcoming short channel effects at this size scale. Individual silicon nanowire field-effect transistors have been shown to exhibit transistor properties that are comparable to bulk single-crystalline silicon devices. However, the transport properties of nanowire devices strongly depends on the nature of the nanowire surface. For example, hysteretic behavior of the threshold voltage is commonly observed due to the presence of surface and interface charge-trapping states on the nanowire surface. This surface dependence potentially limits transistor reliability. Additionally, the amount of energy and time required to align these nanowire components into a controlled high-density planar layout remains a significant hurdle for widespread application.

Herein, we demonstrate that Si nanowires grown vertically from a Si (111) substrate can be used as active components in a vertical FET design featuring a surround gate geometry. In order to fabricate Si VINFETs, Si nanowires were grown in a vertical orientation on degenerately B-doped p-type (p<0.005 ohm-cm) Si (111) substrates as previously demonstrated. By way of example and not limitation, the wires were synthesized by the vapor-liquid-solid (VLS) growth mechanism in a CVD reactor using a SiCl₄ precursor, a BBr₃ dopant source, and metal nanoparticle growth-directing catalysts.

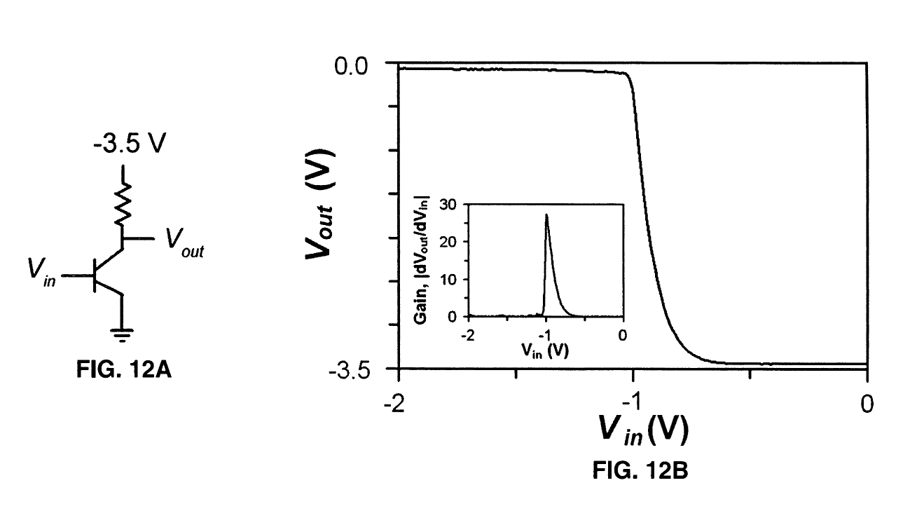

FIG. 9A is a scanning electron microscope (SEM) image of Si nanowires grown from 50 nm Au colloids. Transmission electron microscope (TEM) analysis confirms that these nanowires are single-crystalline and grow along the (111) direction off of an Si (111) substrate. Si nanowire arrays grown by the above method exhibit narrow diameter distributions with standard deviations (typically ≦9%) equal to the colloids from which they were grown.

Although the nanowires shown in FIG. 9A were grown with Au colloids, similar results have been achieved using other nanoparticle compositions such as industry-friendly Pt or Ti. Finally, positional alignment of these nanowires can be achieved by controlling the position of the nanoparticles, as well as using other methods including nanoimprint lithography and e-beam lithography. Thus, the dimensions and positioning of nanowire arrays can be accurately controlled to create suitable substrates for VINFET fabrication.

FIG. 9B is a TEM image of an Si nanowire surrounded in a conformal SiO₂ coating after dry oxidation at 850 C to form the gate dielectric. The scale bar in both FIG. 9A-9B is 50 nm.

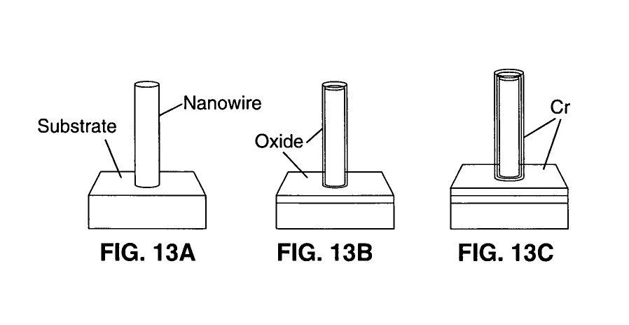

FIG. 10A illustrates an embodiment of a VINFET design according to the invention. These devices are fabricated using conventional very-large-scale integration (VLSI) processing, but without the need for post-growth assembly. Transistor structures having a surround gate structure have been taught and demonstrated herein to have the following advantages: (1) increased transistor density per unit area, due to the 3-dimensional device geometry; (2) a highly-efficient ‘stranglehold’ gate geometry resulting in excellent subthreshold behavior; (3) a 35% reduction of short-channel effects when compared with over double-gate devices.

It should also be appreciated that the ability to incorporate longitudinal and co-axial heterostructures into these nanowires allows future design flexibility, such as the on-chip incorporation of vertical SiGe heterostructures, for on-chip thermoelectric cooling. Furthermore, the nanowires can be embedded in a low charge trap-density SiO₂ toward reducing or eliminating hysteresis therein making transistor properties more consistent and reproducible. Si VINFETs are more readily integrated and technologically significant than prior ZnO and CuSCN VINFETs. Furthermore, the unique performance advantages demonstrated herein for the Si and Ge vertical integrated transistors due to the surround gate design have not been demonstrated in these bottom-up materials.

In this implementation, these vertically grown silicon nanowires were thermally oxidized to create uniform thermal oxides as dielectrics. A typical device in this case having a ˜20-30 nm Si nanowire diameter, surrounded by approximately 30-40 nm of high-temperature gate oxide, and a Cr metal gate length of approximately 500-600 nm. More accurate values of gate-oxide thickness and nanowire channel diameter for specific devices have been obtained from TEM imaging, such as shown in FIG. 10B. Both the gate-oxide thickness and nanowire channel diameter can be easily reduced below 10 nm via conventional high-temperature thermal oxidation and SiO₂ etching chemistry. Initial VINFET devices were fabricated from nanowire arrays catalyzed by low-density nanoparticle arrays. Details about the fabrication process are described in the supplementary information. Each transistor device preferably contains a plurality of nanowires per drain contact pad, such as for example on the order of from six to many hundreds, and more preferably between approximately 8 to 269. FIG. 10B-10D depicts images from a top-down view, perspective view and cross-sectional SEM view of a typical VINFET device according to the invention.

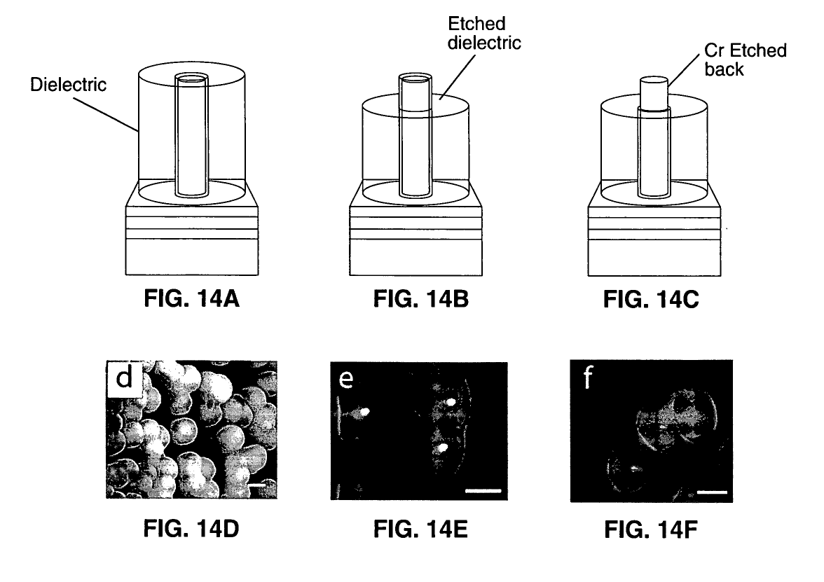

FIG. 11A-11D illustrate characteristics for the fabricated VINFET devices. Typical drain-source current (I_{ds}) vs. drain-source voltage (V_{ds}) measurements at various gate voltages (V_{gs}) indicate that B-doped VINFETs behave as accumulation-mode p-type transistors (FIG. 11A). The application of a negative (positive) V_{gs} results in an increase (decrease) of I_{ds}, due to the increase (decrease) of majority hole carriers. The V_{gs} value at which the I_{ds} is effectively turned on and accumulation begins is defined as threshold voltage (Vₜ). This is further demonstrated in the plot of I_{ds} vs. V_{gs} at different V_{ds} values for the same device (FIG. 11B). The average threshold voltage for 11 different devices was found to be 0.25 V±0.17 V (1σ). This threshold voltage is consistent with the expected values for nanowires with doping densities around 2×10¹⁶ cm⁻³. Additionally, no dependence on the rate or direction of V_{gs} on the Vₜ was observed in any of these transistor devices. This is illustrated by the lack of hysteresis in the I_{ds} vs. V_{gs} curves when the V_{gs} is varied from negative to positive to negative values (see FIG. 11C and a more detailed section in FIG. 11D) at rates varying from 0.01-3 V s⁻¹. This is indicative of a very low number of charge-trapping states in or near the Si/SiO₂ gate oxide interface, and illustrates that consistent, reproducible transistor performance can be achieved with minimal outside ambient dependence, by embedding these devices in SiO₂.

The significant figures of merit of transistor performance include the transconductance (gₘ), the device mobility (μ), on-off current ratio (Iₒₙ/I_{off}), subthreshold slope (S), and the drain-induced barrier lowering (DIBL). The transconductance is obtained from the slope of the linear region in the I_{ds} vs. V_{gs} plot at −1 V_{ds}. The gₘ for all eleven devices ranged from 0.2 to 8.2 μS. Accurate comparison with other transistor devices requires normalizing the transconductance with the effective channel width (W_{eff}). Assuming W_{eff} equals the number of nanowires in each pad multiplied by the diameter of each nanowire, the normalized transconductance of these devices was found to range from 0.65 to 7.4 μS μm⁻¹. These values are comparable to those reported for thin silicon-on-insulator (SOI) MOSFET (5-12 μS μm⁻¹)²⁶ and p-type SiNW (0.045-11 μS μm⁻¹) devices.

The device mobility of an individual nanowire is extrapolated from its transconductance via the equation; μ=gₘ*L²/(C N V_{ds}), where L is the gate length, N is the number of nanowires, and C is the gate capacitance for an individual nanowire. The gate capacitance is described by the equation; C=2 π ∈₀ ∈_{SiO2} L/ln(r_{g}/r_{nw}), where ∈_{SiO2} is the dielectric constant of the gate SiO₂, r_{g} is the inner radius of the gate electrode, and r_{NW} is the nanowire radius. The hole mobilities, averaged from all V_{ds} values between −0.25 and −2.5 V_{ds}, range from 11-97 cm² V⁻¹s⁻¹ with an average mobility of 35 cm² V⁻¹s⁻¹. These hole mobilities are comparable to those reported for unfunctionalized p-type silicon nanowires (20-100 cm² V⁻¹ s⁻¹), and close to the best reported values of p-type SOI MOSFETs (˜180 cm² V⁻¹ s⁻¹).

The Iₒₙ/I_{off}, S, and DIBL can be extracted upon plotting the I_{ds} vs. V_{gs} on a logarithmic scale (FIG. 11C, 11D). The Iₒₙ/I_{off} ratio is the ratio of I_{ds} at current saturation (Iₒₙ) to I_{ds} at depletion (I_{off}). Iₒₙ/I_{off} ranges from approximately 10⁴ to 10⁶ for all devices. Small DIBL is indicative of reduced short channel effects, and is estimated by measuring the shift in Vₜ at a low and high V_{ds}. The DIBL for a typical device is 40 mV per −1 V_{ds}, which is comparable to previously reported values for FINFETs. This figure of merit is expected to become more significant upon further reduction of the gate length. Finally, the minimization of the subthreshold slope is necessary for low power switching applications in digital electronics. The S value for a typical device having a 300 Å gate oxide shell is 120 mV/decade. Although this is approximately double the theoretical room temperature limit of 60 mV/decade, it is much smaller than typical values obtained for nanowire devices with back-gate or top-gate geometries (typically >300 mV/decade). Further reduction of S is possible by using thinner gate oxides and high-k materials as the gate dielectric.

The full I_{ds} vs. V_{ds} curves for all devices have a small nonlinearity at negative V_{ds}, and are rectifying with a one order of magnitude decrease in current at positive V_{ds} (Inset in FIG. 11A). Such nonlinearity in the positive and negative V_{ds} is expected as there are two different Si contacts: a large area (˜1 cm²) source contact to the degenerately doped p-type Si substrate, and a small area (˜4500 nm²) medium-doped p-type nanowire drain contact. This nonlinearity is partly due to the large resistance of a Schottky barrier at the p-type nanowire drain. Decreasing the contact resistance will result in better transistor performance by effectively increasing gₘ, Iₒₙ/I_{off}, and μ. The minimization of series contact resistance at the sub-20 nm scale still remains a significant challenge for the semiconductor industry.

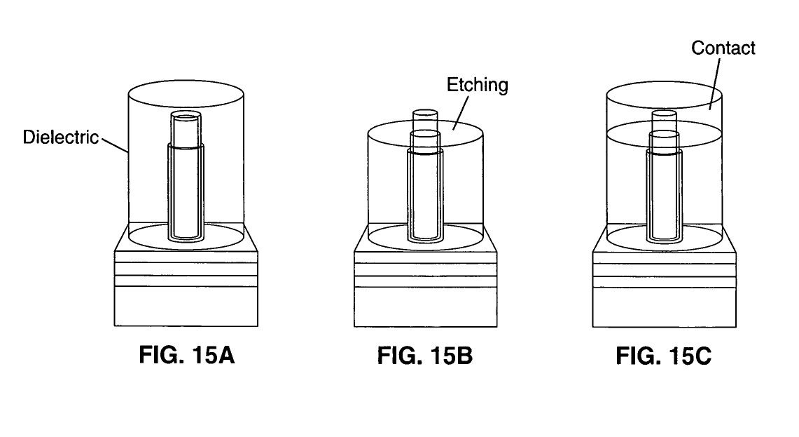

FIG. 12A is an inverter circuit using resistor-transistor logic (RTL) to demonstrate the feasibility of using these devices for digital logic applications. This structure was fabricated by connecting a 200 MΩ resistor to one of our p-type VINFETs in series. When the input voltage is ˜−0.9 V, the output voltage switches between the source voltage (0 V) and the drain voltage (−3.5 V). A large voltage gain of approximately 28 was exhibited, as extracted through differentiating the input and output voltage (left inset in FIG. 12B), which is evidence that these are high-performance devices suitable for use in microelectronic applications. The ideal inverter resistor should have a resistance value preferably in a range between the on and off state transistor resistances. Therefore, future on-chip logic integration using properly gated VINFETs as resistors can be easily fabricated via source patterning SOI substrates.

The described Si VINFET device implementations represent a novel platform for silicon nanowire electronics that combine the epitaxial growth of silicon nanowires with aspects of top-down fabrication. These unoptimized devices already show transport properties comparable to standard planar MOSFETs. Future optimization of the processing, device geometry, doping concentration, the use of high-k dielectrics, as well as gate length reduction may competitively position these devices over high efficiency FINFETs in the sub-10 nm regime.

### Embodiment of VINFET Fabrication Procedure

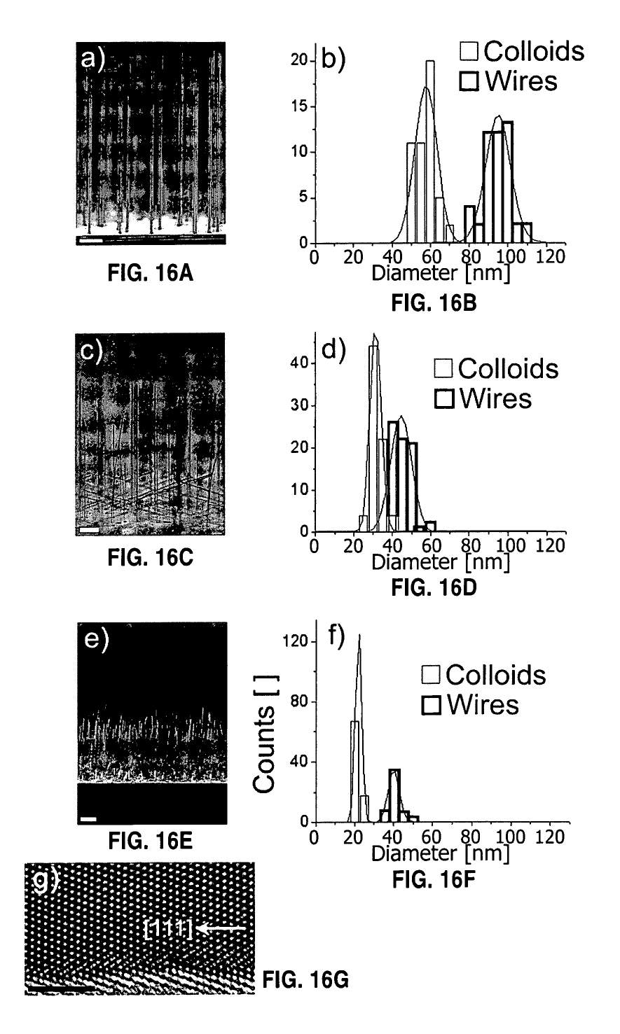

FIG. 13A-13C illustrate an example embodiment of a generalized process for Si VINFET fabrication. In FIG. 13A Si nanowires are grown vertically from a Si (111) substrate. In FIG. 13B a gate dielectric layer is formed, for example using thermal oxidation of the Si nanowire to form SiO₂ as a gate oxide dielectric. In FIG. 13C a Cr gate material is sputtered onto the nanowires to achieve a conformal coating.

The following describes this processing in greater detail. Nanowire growth is performed as depicted in FIG. 13A. Next, the nanoparticle catalysts are etched away, such as by using aqua regia followed by a standard water and isopropanol rinse and a 7 min 300 W O₂ plasma clean. Nanowires having diameters greater than 40 nm and aspect ratios less than 40 are mechanically resilient enough to remain vertical after the standard pre-gate oxide thermal oxidation cleaning procedure despite solvent surface tension forces (smaller diameters and larger aspect ratios were not measured). The substrates were oxidized at 850° C. for 4-8 hours to achieve the desired gate SiO₂ dielectric thickness as depicted in FIG. 13B.

The Cr gate metal is then formed, in this case by sputtering to achieve a conformal 50-100 nm coating, as seen in FIG. 13C. Alternatively, LPCVD techniques can be used to deposit the desired gate materials (i.e., poly-Si, metal silicides) for threshold voltage tuning.

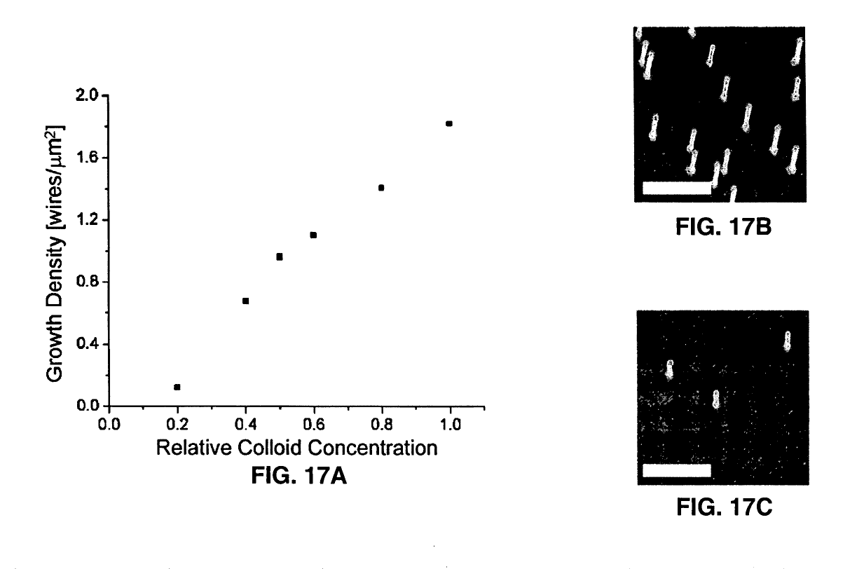

FIG. 14A-14F illustrates additional fabrication steps FIG. 14A-14C and corresponding SEM images. In FIG. 14A a layer of approximately 750-4000 nm of conformal low pressure chemical vapor deposition (LPCVD) SiO₂ dielectric was deposited onto the gated nanowires and substrate, as depicted schematically in FIG. 14A with a corresponding SEM image shown in FIG. 14D. A gate pattern was then defined, such as via standard photolithographic techniques. After developing of the photoresist gate pattern, etch windows were created by plasma etching, and/or a combination of chemomechanical polishing and SiO₂ plasma etching techniques of the exposed SiO₂ areas, thus exposing the Cr nanowire tips as depicted in FIG. 14B and FIG. 14E. For example, plasma etching can be performed using a LAM Research Corporation AutoEtch Plasma Etch System. At this point in the process the tips of the nanowires are still coated with the Cr gate metal. This material must be removed so as to prevent electrical shorting between the drain and gate electrodes. The undesired Cr was etched-back, removed, as depicted in FIG. 14C and FIG. 14F. The etchant may comprise, for example, a photomask etchant, such as Cr-7 Photomask etchant from Cyantek. All SEM scale bars correspond to 1 μm, and all images are obtained at a tilt angle of 30°.

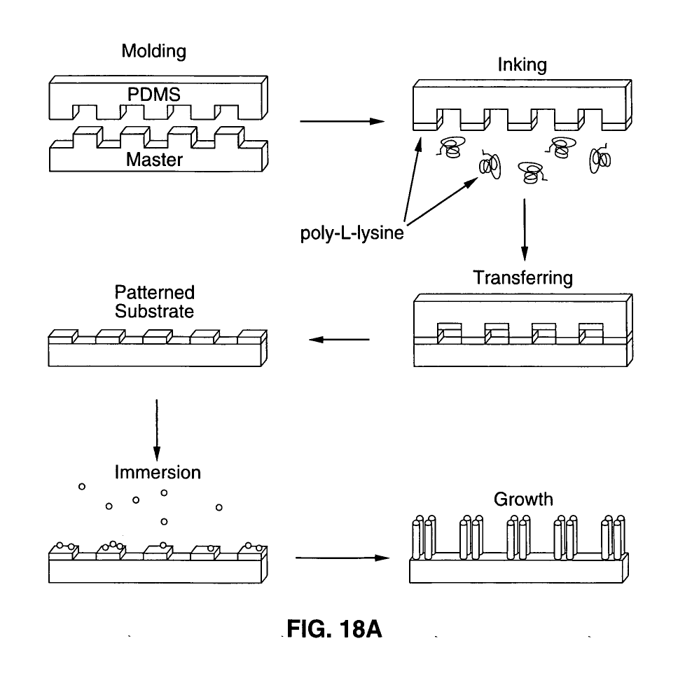

FIG. 15A-15C illustrate another stage of VINFET fabrication. A second coating of dielectric, in the range from approximately 300-750 nm, such as LPCVD SiO₂, was deposited onto the substrates to electrically isolate the gate and drain materials as depicted in FIG. 15A. Drain pads were defined, for example 70 μm×70 μm square drain pads, such as by photolithography methods. The nanowire tips were subsequently exposed via SiO₂ plasma etching. In addition, SiO₂ was preferably removed from the top 50 nm of the nanowires in order to increase the contact surface area, resulting in the structure depicted in FIG. 15B. Contacts are formed, in this case from Ni (50 nm)/Pt (30 nm) sputtered onto the drain regions, and NiSi contacts formed after a two minute rapid thermal annealing treatment at 400° C. which results in the structure shown in FIG. 15C. Before the final source contact is made, photoresist is preferably spun onto the top device side of the substrate to protect the nanowire circuitry. Contacts, such as Al, were thermally evaporated onto the backside of the substrates, after oxide removal, such as via SiO₂ plasma etching and 10:1 buffered HF. Preferably, the device was subsequently annealed, for example at 300° C. to achieve lower contact resistance.

Threshold Voltage Analysis.

An approximate analytical function for vertical cylindrical FET devices has been previously developed by Sharma, Zaidi, Lucero, Brueck, S. R. J. & Islam, in an article entitled “N. E. Mobility and transverse electric field effects in channel conduction of wrap-around-gate nanowire MOSFETs” published in IEEE Proceedings-Circuits Devices and Systems 151, 422-430 (2004). In the case of our system, having p-type nanowires with a Cr gate electrode, the threshold voltage (Vₜ) can be approximated by the following formula:

$${V}_{t} = {V}_{FB} + 2 {Φ}_{F} + \frac{q {N}_{A} {r}_{NW}^{2}}{2 {ɛ}_{0} {ɛ}_{SiO 2}} ln ( 1 + \frac{{t}_{OX}}{{r}_{NW}} ) \qquad ( 1 )$$

where V_{FB} is the flatband voltage (the voltage that is applied to the gate electrode at which the Fermi energy of the gate electrode lines up with the Fermi energy of the nanowire channel), r_{NW} is the nanowire radius, t_{Ox} is the gate oxide thickness, and N_{A} is the acceptor concentration in Si. The value of φ_{F} is given by the formula:

$${Φ}_{F} = \frac{kT}{q} ln ( \frac{{N}_{A}}{{n}_{i}} ) \qquad ( 2 )$$

where nᵢ is the intrinsic carrier concentration in Si. V_{FB} can be deduced by the following equation;

$${V}_{FB} = {Φ}_{M} - χ - \frac{{E}_{g}}{2} - {Φ}_{F} \qquad ( 3 )$$

where Φ_{M} is the gate work function, x is the electron affinity of Si, and E_{g} is the band gap of silicon. Solving Eq. (1) for N_{A} using the average observed threshold voltages gives an average carrier concentration of 5×10¹⁶ cm⁻³. More accurate analysis of the influence of carrier concentration on threshold voltage at these small length scales can be derived using drift-diffusion simulations.

### 4. Controlled Growth of Si Nanowire Arrays for Device Integration.

In this section silicon nanowires are synthesized in a controlled manner for their practical integration into devices. Gold colloids were utilized for nanowire synthesis by the vapor-liquid-solid (VLS) growth mechanism. Using SiCl₄ as the precursor gas in a chemical vapor deposition system, nanowire arrays were grown vertically aligned with respect to the substrate. By manipulating the colloid deposition on the substrate, highly controlled growth of aligned silicon nanowires was achieved. Nanowire arrays were synthesized with narrow size distributions dictated by the seeding colloids and with average diameters down to 39 nm. In these demonstrations the density of wire growth was successfully varied from approximately 0.1-1.8 wires/μm². Patterned deposition of the colloids led to confinement of the vertical nanowire growth to selected regions. In addition, Si nanowires were grown directly into micro-channels to demonstrate the flexibility of the deposition technique. By controlling various aspects of nanowire growth, these methods will enable their efficient and economical incorporation into devices.

Silicon nanowires (SiNWs) have been identified as useful building blocks for nanoscale electronic and thermoelectric devices. To realize their full potential in applications, however, SiNW must be integrated efficiently and economically into various device architectures. Devices have been constructed around single, or several, dispersed SiNWs, and methods have been developed to manipulate as-grown nanowires into geometries amenable to large-scale device fabrication. Alternatively, controlled growth of SiNWs in predetermined configurations would eliminate much of the processing associated with device fabrication. Furthermore, vertical growth (substantially perpendicular to the substrate) allows three-dimensional integration for more complex structures, such as vertical integrated field-effect transistor (VFET) arrays. Such arrays could afford higher transistor densities and novel three-dimensional logic or memory architectures.

The VLS growth mechanism is a synthetic technique which is particularly well-suited to controlling SiNW growth. VLS growth by chemical vapor deposition (CVD) can produce epitaxially aligned, single-crystalline wires. Specifically, SiNWs may be grown via the VLS process using gold thin films. Metal thin film, however, may not be as well suited to providing good diameter control of the resulting wires due to the randomness of the film breakup at reaction temperatures. Also, precise growth and epitaxial alignment of SiNWs has only been achieved using lithographically defined regions of SiNW growth by thin film evaporation. These methods employ expensive processing techniques with limited control over nanowire size and density.

However, gold colloids can be used to produce well-dispersed and diameter-controlled SiNWs, although simultaneous control over the size, position and epitaxial growth has not been achieved previously. Methods have been taught herein to grow vertically aligned SiNW with controlled dimensions and specific placement by the conventional VLS-CVD synthesis. Using a thin polyelectrolyte layer, gold colloids are electrostatically attracted and immobilized on the substrate to act as seeds for Si nanowires grown using the VLS-CVD method. The diameter of the colloids precisely controls the nanowire diameter. The concentration of the colloid solution controls the density of growth. Micro-contact printing of the polyelectrolyte layer can be used as a means to confine wire growth to patterned regions. Moreover, these versatile techniques facilitate incorporation of vertically aligned SiNWs into more complex systems, such as micro-fluidic channels.

In general, Au colloids are used to define the diameter and position of the SiNWs. Subsequent wire growth occurs along the <111> direction and is vertical due to the epitaxial growth of Si wires from the binary liquid droplet onto the underlying substrate, for example an Si (111) wafer, as previously shown. The colloids were immobilized on the wafer surface, such as adsorbing a thin layer of polyelectrolyte onto the substrate surface, for instance in response to a quick immersion in 0.1 wt % poly-L-lysine. After rinsing with DI water, the substrates were immersed in the Au nanoparticle solution (10¹⁰-10¹¹ particles/mL). It should be noted that the polymer possesses a net positive charge in an aqueous solution at neutral pH and hence adsorbs onto the substrate due to its electrostatic attraction to deprotonated hydroxyl groups on the silica layer. Consequently, the polymer film presents a positively charged surface to the negatively charged Au colloids in aqueous solution, attracting them to the surface. Following a final rinse with DI water and drying, the substrates were used for nanowire growth in a CVD furnace as reported previously.

The precursor molecules utilized for SiNW growth in the CVD system was SiCl₄. Growth of various substrates seeded with Au colloids was conducted at temperatures between 800° C. and 850° C. H₂ (10%) in Argon was used as the carrier gas to flow through the Si precursor bath and into the reaction tube. The substrates were cleaned with acetone and IPA before polymer and colloid deposition. The polymer was presumably ashed by the high reaction temperatures and a reducing H₂ environment. Gaseous HCl, a byproduct of SiCl₄ decomposition in the reaction tube, etched the oxide layer on the Si surface, presenting a clean Si crystal surface to precipitating Si from the binary liquid droplet. Epitaxial deposition of Si at this interface induced growth direction alignment of the nanowire with the crystal face of the Si wafer. Consequently, such alignment could be more difficult using other CVD precursors, such as SiH₄, without separately adding HCl gas or taking special precautions to remove the oxide layer before SiNW synthesis.

SiNWs synthesized by the above method on a Si (111) substrate yielded vertically aligned, single-crystalline wires, as observed by scanning and transmission electron microscopy (SEM and TEM). Wires aligned along the three [−111] directions were also observed, especially in synthesis using smaller colloidal catalysts, but the gas flow rate and reaction temperature were optimized to preferentially grow vertical wires for each colloid system.

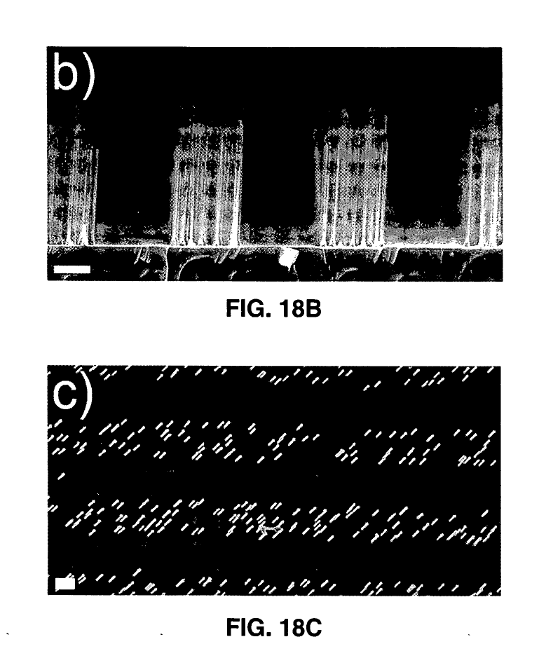

FIG. 16A-16G illustrate nanowire samples and their diameters as formed according to the following. Au colloids are well suited as seeds for controlling the SiNW diameter: The Au colloids act as the seeding metal for nanowire growth by the VLS process, and Au colloids may be synthesized, or obtained commercially, with relatively narrow size distributions. Since each colloid seeds growth for one nanowire, aligned nanowires can be grown with narrow size distributions approaching those of the seed particles. Hence, by seeding wire growth with colloids of different average size, we were able to precisely control the average diameter of the SiNW arrays, as seen in FIGS. 16B, 16D and 16F. Size distributions of both colloids and nanowires were determined from TEM micrographs. SiNWs grown from Au colloids of 50 (56 ±5.0), 30 (30±3.3), and 20 (20±2.1) nm diameters were 93±7.4, 43±4.4, and 39±3.7 nm in diameter, respectively.

Extensive TEM characterization as shown in FIG. 16G indicates that these wires are single crystalline in nature. We would like to emphasize that although monodisperse silicon nanowires can be synthesized using monodispersed Au colloids as seeds, epitaxially grown, monodispersed silicon nanowires were grown in this novel chloride based CVD process.

The SiNWs were wider than their respective seed particles due to the influx of Si into the colloids and alloy formation during the synthesis. The seed droplets swell in size until the critical supersaturation concentration is reached, at which point Si begins precipitating on the Si (111) surface below. The interface between the Au—Si droplet and the substrate determines the area of precipitation of Si, and thus the SiNW diameter. Despite their larger size, however, the nanowires have approximately the same relative standard deviation of diameter as the colloidal solutions used to seed their growth. The standard deviations of the 50, 30 and 20 nm colloids used in this study are ±8.8%, 11%, and 11% of the average size, respectively. The standard deviations of the wires grown from these colloids are ±7.9%, 10%, and 9.5% of the average size, respectively. This data suggests that precise diameter control of nanowires grown by this method is limited only by the size distribution of the seed particles. Hence, appropriate colloidal solutions could be used to grow monodisperse nanowire arrays.

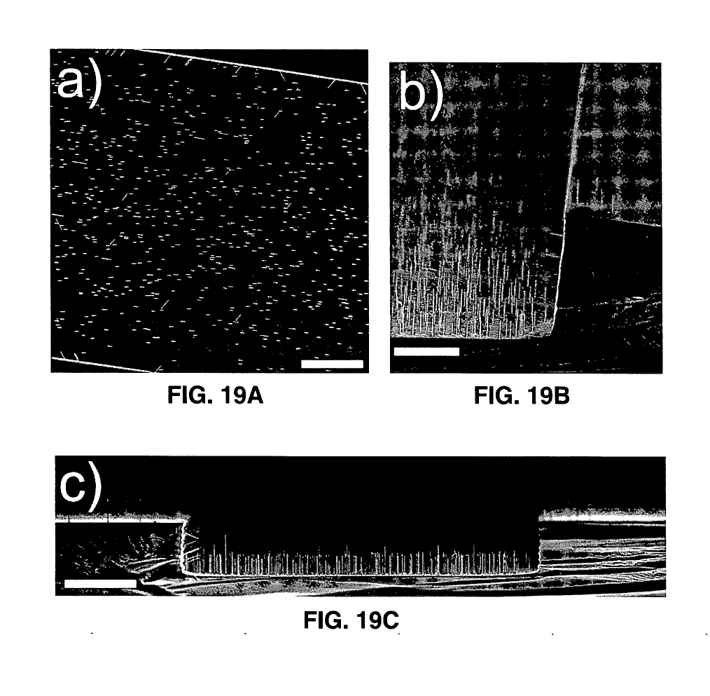

FIG. 17A-17C illustrate nanowire growth density in response to colloid concentration. SiNW growth density depends on the relative concentration of the seeding solution as seen in the graph of FIG. 17A. In this example, all colloid solutions were diluted from the same stock solution. The images illustrate typical nanowire growth at 4/5 in FIG. 17B and 2/5 dilution in FIG. 17C, with 1 μm scale bars shown on each image.

The density of nanowire growth is critical to proper device function. By varying the concentration of the seeding solution (using 50 nm Au colloids as an example), we were able to control the seeding density on the substrate surface. The graph of FIG. 17A shows the relationship between nanowire growth density, as determined from SEM images, for example those shown in FIG. 17B and FIG. 17C, and dilution of the gold colloid stock solution. Wires were seeded with densities ranging over an order of magnitude, from approximately 0.1-1.8 wires/μm³. In general, a beneficial 1-to-1 nanoparticle/nanowire ratio can be achieved although it was observed that optimal growth conditions varied slightly with nanowire seeding density.

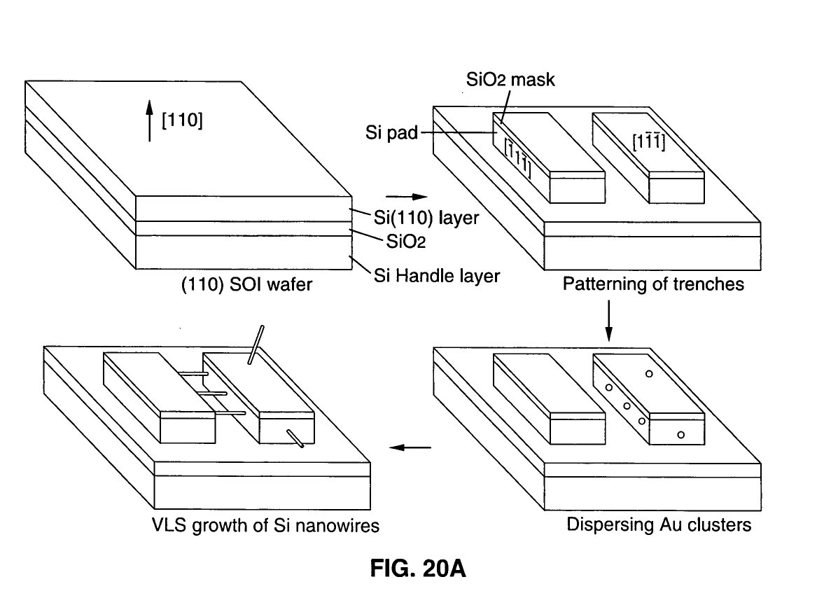

FIG. 18A-18B illustrate an example of polydimethylsiloxane (PDMS) patterning of Au colloids. Spatial control over SiNW growth is achieved by patterning regions of seed particles, such as by using micro-contact printing. The steps of PDMS patterning of Au colloids is shown schematically in FIG. 18A. Briefly, a PDMS stamp is molded to the relief pattern of a photoresist master. In this example a polydimethylsiloxane (PDMS) stamp was made using a photoresist master of 2 μm lines with 2 μm separation. After curing the polymer, the stamp is removed from the master and “inked” with a solution of poly-L-lysine, such as by the same method described above for deposition on the Si substrates. The stamp pattern is transferred to the Si (111) substrate, and the pattern was transferred to the substrate, such as by placing the stamp on the substrate and heating at 70° C. for 5 minutes. After this the substrate with the pattern is immersed in the Au colloid solution. For example immersion in a 50 nm Au colloid solution for a short time, such that colloids only adhere to the polyelectrolyte and not the bare Si. The colloid-patterned substrate is then grown using the conventional VLS-CVD synthesis, resulting in a corresponding pattern of SiNW arrays.

A cross-sectional SEM image of PDMS patterned SiNW growth is shown in FIG. 18B, with FIG. 18C showing a plan-view SEM image of the same. Scale bars on each image are 1 μm. The resulting growth, seen in the images is strictly confined to the regions of poly-L-lysine deposition. The plan-view SEM image (FIG. 18C) shows a small portion of the pattern, which is consistent over several square millimeters, which corresponds with the extent of the stamped area that was immersed in the colloid solution.

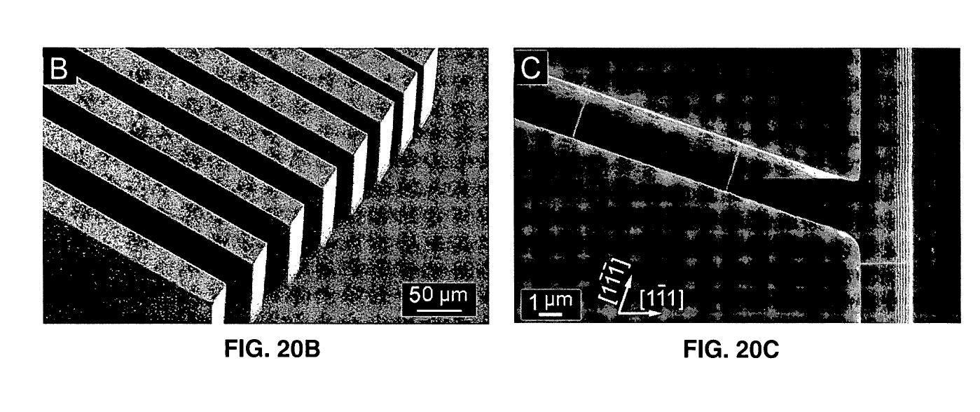

FIG. 19A-19C illustrate growth of SiNWs directly in a micro-channel. This colloid-seeded growth method represents a convenient way to incorporate nanowires into other systems, such as micro-fluidic systems. The micro-channels shown in FIG. 19A-19C for this example were 8 μm deep and 40-100 μm wide. They were etched into a Si (111) wafer by deep reactive ion etching (DRIE) using SF₆/O₂ as the etchant and C₄F₈ as the sidewall passivation gas. The middle portion of a micro-channel array was covered with an O₂ plasma-treated piece of blank PDMS. The PDMS encloses the micro-channels by adhering to the top Si (111) surface. The colloid deposition method resembles those discussed above. First, a droplet of the poly-L-lysine solution was placed on one end of the micro-channel array, touching the PDMS. The solution was transported by capillary action to the open end of the channels. After rinsing in DI water, the PDMS was replaced and a droplet of 50 nm Au colloid solution was placed where the polymer solution had been. In the same manner as before, the solution flowed to the opposite end of the channels, and then the substrate was rinsed again. The wires were grown directly in the channels under the same conditions as previous synthesis.

FIG. 19A is a plan-view SEM image in which it is seen that nanowire growth is almost completely confined to the floor of the channel. FIG. 19B shows an approximate 45° tilt view while FIG. 19C is a cross-sectional SEM view of the same channel. Scale bars in each image are 10 μm in length. As can be seen from these images, nanowire growth and vertical alignment was not affected by either the roughness of the floor of the channel, due to etching, or any changes in precursor gas flow dynamics near the channel walls. Furthermore, use of the PDMS resulted in restricting gold colloid deposition predominantly to the floor of the micro-channel. There is insignificant nanowire growth on the top surface of the substrate, so the micro-channels may be resealed with PDMS to function as a micro-fluidic device, such as for macromolecular separation based on SiNWs as diffusion barriers.

In summary, using directed colloid seeding for VLS-CVD SiNW synthesis provides precise control over nanowire diameter, growth density, and spatial distribution. At the same time, the SiCl₄ precursor is highly effective for the growth of vertically aligned, single-crystalline SiNWs. Moreover, these techniques facilitate the direct integration of nanowires into complex systems such as micro-fluidic devices. The versatility of the growth control methods described herein benefit from the use of SiCl₄ as the gas phase precursor. Other Si precursors (e.g., SiH₄) offer less flexibility of substrate preparation and vertical SiNW alignment as they require separately incorporating HCl gas. Specifically, the aligned growth of SiNWs makes this process well-suited for fabricating array devices, such as VINFET circuits, and two-dimensional photonic crystals. Additionally, these arrays may serve as scaffolding for the deposition of other materials for an even wider range of applications. Such in-place growth control will aid the incorporation of nanowires into devices.

### 5. Si Nanowire Bridges in Micro-trenches & Integration of Growth in Fabrication.

Silicon nanowires are attractive building blocks for nano-scale electronic systems due to their compatibility with existing semiconductor technology. Studies have focused on their synthesis, with considerable advances made in the control of structures, electrical and thermal properties. For practical applications, different strategies have been explored to fabricate nanowire-based devices. Pick-and-place approaches have succeeded in making individual devices such as field effect transistors (FETs), isolated thermal bridges and chemical sensors, but the approach is time-consuming and unsuitable for large scale manufacturing. The Langmuir-Blodgett technique has been utilized as a powerful and low-cost approach to align nanowires and make large scale arrays of devices, showing a significant advance towards nanowire-based integrated circuits.

However, in some circumstances, instead of following the “bottom-up synthesis first, assembly and top-down fabrication next” approach, it is more beneficial to grow nanowires precisely and rationally in pre-determined device architectures. Direct integration of nanowire growth into the fabrication process markedly simplifies procedures and avoids deterioration of nanowires in some micro-fabrication or nano-fabrication processes. In this section, Si nanowires have been grown laterally in micro-trenches pre-fabricated on silicon-on-insulator (SOI) wafers, demonstrating that nanowire growth and device fabrication can be achieved simultaneously. Lateral bridging growth was first demonstrated for GaAs nanowires and recently for Si nanowires. However, well-controlled growth and device operation were not achieved. Accordingly, in this section epitaxial growth of bridging Si nanowires and effective control of diameters, lengths, and densities is demonstrated. Electrical measurements of these Si nanowires indicate that nanowires in trenches could serve as versatile active components in circuits.

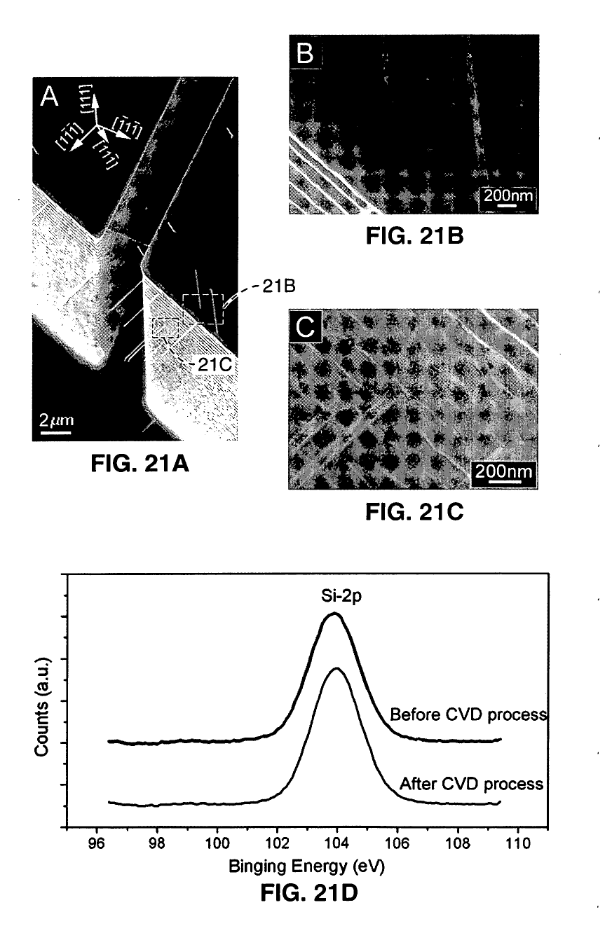

FIG. 20A-20C illustrates the use of nanowires grown in trench structures to create bridging nanowires. In FIG. 20A a schematic illustration of Si nanowire bridge fabrication is shown connecting between two vertical Si{111} surfaces on (110) oriented SOI wafers. The idea of nanowire-in-trench structures is based on epitaxial growth of Si nanowires. Si nanowires grow preferentially along <111> directions. If the vertical {111} planes contained in a Si(110) wafer are exposed by vertical etching, Si nanowires can be grown laterally, bridging the two face-to-face {111} surfaces, as illustrated in FIG. 20A. In this procedure, fabrication started with a heavily doped Si(110) SOI wafer, into which trenches were micro-fabricated photolithographically, such as by proper alignment of the substrate and the pattern so that the {111} planes were exposed.

FIG. 20B shows a scanning electron microscopy (SEM) image of a group of parallel trenches. After forming these trenches, Au clusters were dispersed on the substrate as catalysts for vapor-liquid-solid (VLS) growth of nanowires carried out in a subsequent chemical vapor deposition (CVD) process using SiCl₄ as the precursor. It is expected that when a growing nanowire impinges into the opposite sidewall, an electrical or thermal connection is automatically made with the bridging Si nanowire being the active unit, the Si pads confine the trench as electrodes, and SiO₂ layer underneath as the insulator/dielectric barrier.

FIG. 20C shows the SEM image of such a structure. Two nanowires with diameter of approximately 80 nm have bridged the 2 μm wide (1 1̅ 1̅) trench and one nanowire has bridged in the (1 1̅1) trench. Excellent epitaxy and interface cleanliness shown here are two of the advantages of the CVD process based on SiCl₄ precursor and Au clusters. These are crucial for obtaining devices with high quality.

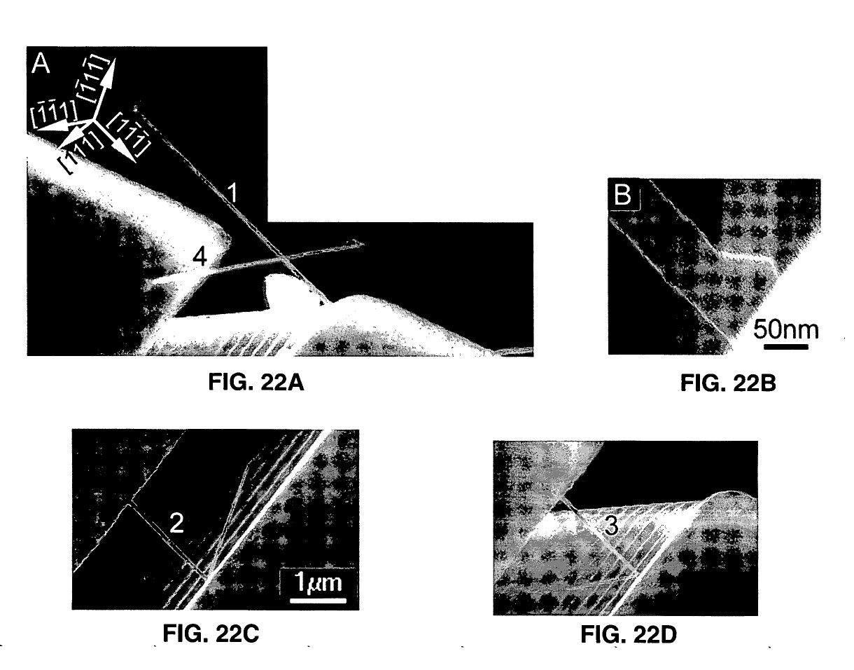

FIG. 21A-21D illustrate in greater detail epitaxial alignment and interface cleanliness for Si nanowire growth in trenches. Epitaxial growth, as the foundation of this work, is discussed first. For the samples shown, the SiO₂ mask used in photolithography to form the trenches, was removed before growth to allow nanowires to grow on the top exposed Si(110) surfaces. As shown in FIG. 21A, besides perpendicular growth of nanowires on the {111} vertical surfaces as expected, well aligned nanowires also grew along [11 1̅] and [111] directions on the (110) top surface. It should be noted that <111> crystallographic alignment is exhibited on both Si{111} and {110} surfaces. Crystallographic geometry is illustrated by the projection of four <111> vectors. Similar results were obtained in the epitaxial growth of GaAs nanowires. Moreover, surface roughness was found to have little influence on epitaxy.

In the close-up image of the vertical {111} surface of FIG. 21C, scalloping of the surface is noticeable, which was caused by the deep reactive ion etching (DRIE) cycles during the micro-fabrication of the trenches. Nonetheless, nanowires persisted to grow along the <111> directions without much influence from the local variation of surface orientation. One can conclude that the epitaxially grown Si nanowires always align themselves with crystallographic <111> directions, with the substrate local orientation, such as due to roughness, only affecting which specific <111> direction the nanowires prefer (e.g., nanowires prefer the perpendicular [111] direction for a relative smooth (111) surface).

This alignment is believed to be driven by the energetically favorable <111> growth and facilitated by crystallization at the liquid-solid interface in the VLS process. Here, we stress the uniqueness of our SiCl₄-based CVD synthesis, because no epitaxial alignment as significant as that exhibited herein has been observed in other synthesis methods such as pulsed laser deposition, thermal evaporation of SiO₂ and SiH₄ CVD. This robust tendency for Si nanowires to align along the <111> directions substantially simplifies device fabrication processes, such as by reducing the requirement to perform alignment by etching (to find <111> directions precisely) and polishing of surfaces.

Thin film deposition is a process that could, for example, be performed simultaneously with VLS growth of nanowires in CVD. To prevent potential current leakage through an unintentionally deposited Si film, this film deposition must be minimized especially on the insulating SiO₂ surfaces. The growth conditions chosen in the present work ensure that the deposition rate of thin films is negligible during VLS growth. For example, there is no observable deposition besides nanowires on Si(110) surface in FIG. 21B, nor on Si(1 1̅ 1̅) surface FIG. 21C.

More quantitative results were obtained by X-ray photoelectron spectroscopy (XPS), a surface sensitive characterization technique. As shown in FIG. 21D, there are no differences between the two Si 2p spectra taken from the insulating SiO₂ surface before and after a 30-minute CVD process. Only the chemically shifted Si-2p peaks characteristic of SiO₂ are observed at 103.8 eV while the Si-2p peaks of elemental Si at 99.8 eV are absent (Standard Si-2p peak is 103.3 eV for SiO₂ and 99.3 eV for Si). Basically, the large difference in deposition rates between thin films and nanowires is attributed to the catalytic action of liquid droplets in the VLS growth. Furthermore, in SiCl₄ CVD, thin film growth is further suppressed by the well documented etching effect of Cl species generated at high temperatures.

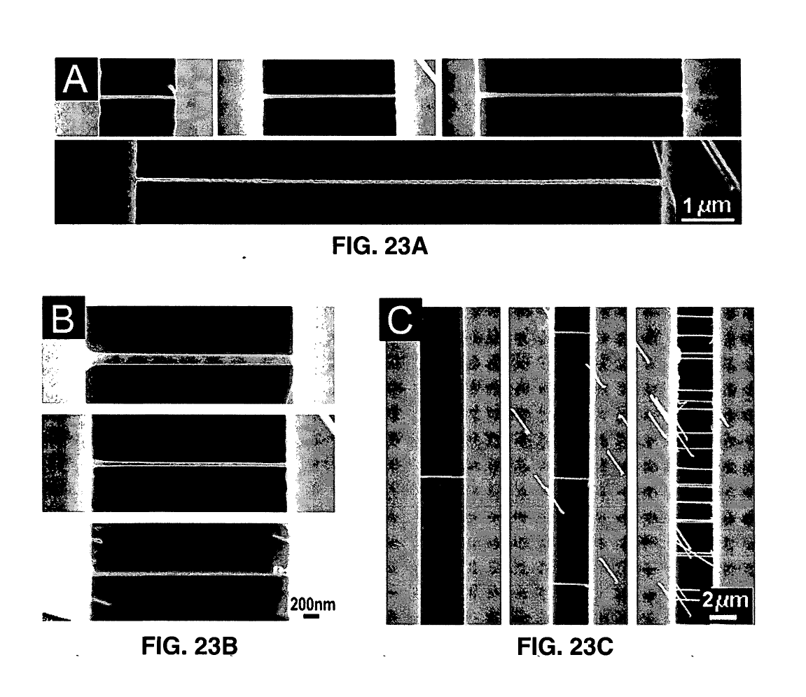

FIG. 22A-22D illustrates evaluating nanowire connections between the Si nanowires and the trench sidewalls using overgrown nanowires. For device applications, it is important to ascertain the characteristics of connections formed between the Si nanowires and the sidewalls. This issue was investigated in over-grown nanowires with lengths exceeding the widths of trenches. The sample is shown in the figures in which nanowires with average lengths of 4 μm were grown in 2 μm wide trenches. Nanowires 1 and 2, as indicated on the SEM images, are located in different positions of a trench, and nanowire 3 located in another trench, were arranged together for easy comparison as seen in FIG. 22A. Nanowire 1 grew in a straight path along the [ 1̅11] direction with no blockage and is used as a reference for the other two nanowires. Nanowires 2 and 3 shown in FIG. 22C-22D, which are grown along the [ 1̅1 1̅] direction, reached the opposite ( 1̅11) walls but continued to grow in a backwards direction along [ 1̅1 1̅] and [ 1̅ 1̅1]. The backward growth directions were determined to still be <111> exclusively by extensive measurements of the angles and comparison with the nanowires grown on the (110) surface.

There are three possible backward directions for a given nanowire. Specifically, they are [111], [ 1̅1 1̅] (nanowire 2), and [ 1̅ 1̅1] (nanowire 3) for a nanowire originally growing along [1 1̅ 1̅] direction. This observation is consistent with the <111> alignment in epitaxy discussed above. The mechanism of backward growth directly indicates that nanowires should self-weld with the opposite sidewall and form solid connections as shown in FIG. 22B. The mechanical rigidity was further confirmed in the nanowire deflection experiments carried out using atomic force microscopy, which will be reported elsewhere. The nanowire-to-substrate connections shown here are different from disk formation reported previously possibly due to different growth conditions such as the precursor molecules and the temperature.

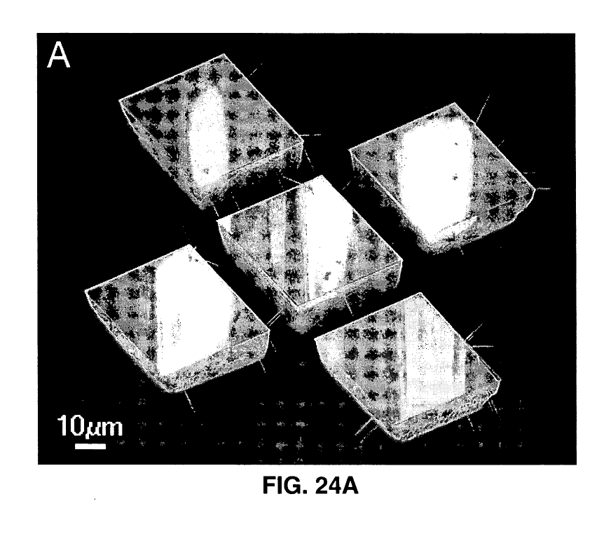

FIG. 23A-23C depicts nanowire fabrication in which the diameters (FIG. 23A), lengths (FIG. 23B), and densities (FIG. 23C) of the nanowires are tightly controlled. Control can be achieved, such as for this example, utilizing the Au cluster catalyzed growth process. First, the lengths of nanowires can be tailored to fit in trenches of varying widths by controlling growth time. For instance, FIG. 23A depicts four bridging nanowires with similar diameters (˜75 nm) having lengths of 1.5, 2.5, 4 and 10 μm respectively.

Second, the diameters of nanowires can be defined by the sizes of Au clusters. As shown in FIG. 23B, the diameters of nanowires grown from 100, 50 and 10 nm Au clusters are 140, 70 and 35 nm respectively.

Finally, the densities of nanowires in trenches can be controlled by the surface densities of Au clusters. In the example shown in FIG. 23C, densities of 1 wire/50 μm, 4 wires/50 μm and 40 wires/50 μm were obtained by using a series of diluted Au colloids. It is worth noting that nanowire diameter is not controlled independently of nanowire density in thin film catalyzed nanowire growth, where a decrease in diameter is always accompanied by a decrease in density. In contrast, in Au cluster-catalyzed growth, diameters and densities can be controlled independently.

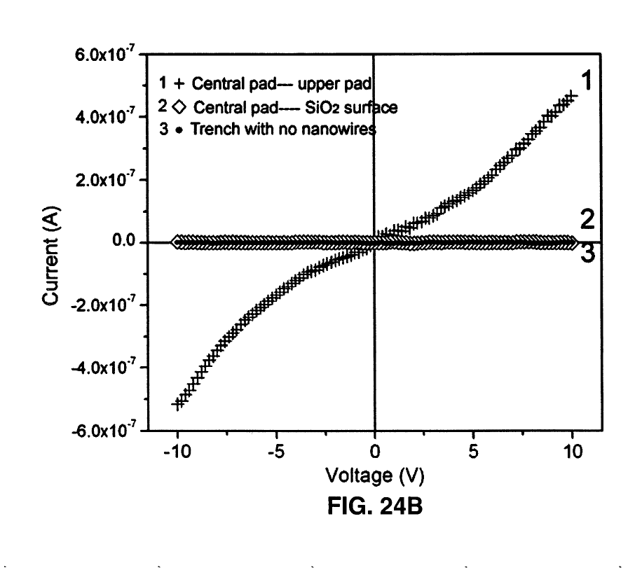

FIG. 24A-24B describes testing the current flow capability of bridging nanowires. FIG. 24A depicts Si pads that were created as electrodes to provide the basis for testing the capability to pass a flow of current through the bridging nanowires, in particular applications of nanowire-in-trench structures in nano-scale electronics. In the example shown in FIG. 24A, we demonstrated the electrical connectivity of a simple network consisting of five Si pads connected by bridging nanowires.

Two tungsten probes were directly placed on top of the pads to perform electrical transport measurement. The results are shown graphically in FIG. 24B. Current-voltage (I-V) curve 1 shows the measurement between the central pad and upper pad with several nanowires in between, indicating current flow through the nanowires. Curve 2 is the I-V measured between the central pad and SiO₂ layer underneath, and curve 3 is from a measurement on a trench with no nanowires bridging. No currents were measured in these cases, consistent with the XPS results, indicating that transport occurred exclusively through nanowire bridges. Furthermore, contact problems existing in the current “fabricating electrodes after growth” approach (e.g., the deterioration of electrode-nanowire interface) are avoided here since the electrodes and nanowires are integrated into one single crystalline piece in the bridge structures. More advanced functions can be realized by further modifications on the prototype devices shown here.

In conclusion, direct integration of nanowire growth into device fabrication has been demonstrated by bridging Si nanowires in micro-fabricated trenches, which provides both growth and fabrication in a more rational and simple manner toward the creation of nanowire-based integrated circuits. The framework of devices can be pre-defined in top-down fabrication before the growth, and structures of the core units (i.e., the nanowires) can be readily realized using the Au clusters catalyzed SiCl₄ CVD synthesis. These new control capabilities make the nanowire-in-trench strategy desirable for various applications, such as chemical sensors, FETs and nanomechanical resonators, and so forth.

Experimental.

Fabrication of trenches: (110) SOI wafers used in the study consist of 20-80 μm thick Si(110) layer, 0.5-2 μm thick thermally grown SiO₂ layer, and having approximately a 400 μm thick Si(100) handle layer. Thermal SiO₂ film with a thickness of from 0.5-1 μm was first grown on a Si(110) surface in H₂O vapor at 1050° C. Patterns designed for trenches were made on spin-coated photoresist by photolithography and then transferred onto the SiO₂ layer by plasma etching. Using the patterned SiO₂ film as the mask, the deep reactive ion etching (DRIE) process was carried to etch the Si(110) layer to expose vertical {111} planes in an inductively-coupled plasma etcher (Surface Technology Systems). Trenches formed after etching reached the insulating SiO₂ layer of the SOI wafer.

Growth of Si nanowires: The SiO₂ mask was etched in 10% HF in some cases before growth, for studying the epitaxy, or for better imaging, while in some cases, it was etched after growth to remove the nanowires on the top surfaces. For dispersion of Au clusters, a drop of 0.1 wt % poly-L-lysine was first deposited on the surface of the substrate followed by rinsing with DI water and drying by N₂. Then, a drop of Au colloids was dispersed on the substrate also followed by rinsing with DI water and drying by N₂. The synthesis was carried in a horizontal hot-wall furnace at 800-850° C. SiCl₄ was used as a precursor and 10% H₂ in Ar was used as both carrier gas and diluted gas.

Characterization: All the images were taken in a JEOL-6400 field emission scanning electron microscope (SEM). X-ray photoelectron spectra (XPS) were obtained in an ultrahigh vacuum chamber equipped with an Omicron EA125 electron energy analyzer and an Omicron DAR400 X-ray source. Binding energy values were corrected using the C-1s peak as reference.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 U.S.C. 112, sixth paragraph, unless the element is expressly recited using the phrase “means for.”

What is claimed is:

1. A field effect transistor, comprising:
a nanowire extending from a substrate base;
a dielectric material surrounding at least a portion of said nanowire;
a gate material surrounding at least a portion of said dielectric material;
said nanowire having an exposed tip, which is not covered with said dielectric material or said gate material; and
a drain material coupled to in contact with said exposed tip of said nanowire.

2. A field effect transistor as recited in claim 1, wherein a plurality of said nanowires extending from said substrate base are coupled to said drain material of a single drain contact pad.

3. A field effect transistor as recited in claim 1, wherein said nanowire extends substantially vertically from a horizontal substrate.

4. A field effect transistor as recited in claim 1, wherein said nanowire is grown from said substrate base.

5. A field effect transistor as recited in claim 4, wherein the growth orientation of said nanowire is controlled utilizing epitaxial crystal growth techniques.

6. A field effect transistor as recited in claim 4, wherein said nanowire is grown from Si or SiGe with any desired type and level of dopants.

7. A field effect transistor as recited in claim 1, wherein said nanowire is grown according to a vapor-liquid-solid (VLS) process.

8. A field effect transistor as recited in claim 7, wherein epitaxial crystal growth is used to grow the nanowire according to a vapor-liquid-solid epitaxy (VLSE) process.

9. A field effect transistor as recited in claim 7, wherein SiCl₄ is utilized as a gas phase precursor, without separately incorporating HCl gas, during growing of said nanowire.

10. A field effect transistor as recited in claim 7, wherein the material or dopant properties may be varied during nanowire growth to form a longitudinally patterned nanowire.

11. A field effect transistor as recited in claim 1, wherein the nanowire diameter is controlled in response to the diameter of an alloy droplet during nanowire growth from the substrate.

12. A field effect transistor as recited in claim 11, wherein a plurality of said alloy droplets are contained within a colloidal metal which is dispersed on the surface of said substrate prior to growth of a plurality of said nanowires.

13. A field effect transistor as recited in claim 12, wherein said colloidal metal comprises gold (Au).

14. A field effect transistor as recited in claim 1, wherein a plurality of said nanowires are grown on said substrate at sites of alloy droplets distributed across at least a portion of the substrate surface as monodispersed metal nanoclusters.

15. A field effect transistor as recited in claim 14:
wherein said substrate is patterned for growing nanowires in a pattern upon selected areas; and
wherein said pattern contains said monodispersed metal nanoclusters selectively disposed on said substrate from which said nanowires are grown.

16. A field effect transistor as recited in claim 15, wherein said substrate is patterned utilizing micro-contact printing.

17. A field effect transistor as recited in claim 1, wherein said field effect transistor comprises a vertical integrated nanowire field-effect transistor which is configured for integration within an electrical device, circuit or system.

18. A field effect transistor, comprising:
a plurality of nanowires grown from a substrate base;
said nanowires are grown utilizing SiCl₄ as a gas phase precursor;
a dielectric material surrounding at least a portion of each of said nanowires;
a gate material surrounding at least a portion of said dielectric material on each of said nanowires;
wherein each of said nanowires has an exposed tip, which is not covered with said dielectric material or said gate material; and
a drain material in contact with said exposed tip of each of said nanowires.

19. A method of fabricating a vertical integrated nanowire field effect transistor, comprising:
growing a nanowire vertically in-place on a substrate;
etching away nanoparticle catalysts;
forming a gate dielectric of a desired thickness;
depositing a gate metal on the nanowire to achieve a conformal coating;
depositing a dielectric onto the substrate;
etching undesired gate metal wherein the nanowire has an uncoated tip;
depositing a dielectric onto the substrate to electrically isolate the gate and drain materials; and
forming a drain pad in contact with said uncoated tip of said nanowire.

20. A method as recited in claim 19, wherein growing of said nanowires comprises:
dispersing metal nanoclusters of a desired diameter over one or more portions of the substrate, or within a pattern; and
epitaxially growing said nanowire from Si to a desired length utilizing SiCl₄ as a gas phase precursor.
